(19) United States
(12) Patent Application Publication
(10) Pub. No.: US 2023/0422509 A1
(43) Pub. Date: Dec. 28, 2023

(54) SEMICONDUCTOR DEVICE AND ELECTRONIC SYSTEM INCLUDING THE SAME

(71) Applicant: Samsung Electronics Co., Ltd., Suwon-si (KR)

(72) Inventors: Seokcheon BAEK, Suwon-si (KR); Seongjun SEO, Suwon-si (KR)

(73) Assignee: Samsung Electronics Co., Ltd., Suwon-si (KR)

(21) Appl. No.: 18/336,497

(22) Filed: Jun. 16, 2023

(30) Foreign Application Priority Data
Jun. 24, 2022 (KR) 10-2022-0077813

(51) Int. Cl. H10B 43/35; H10B 41/35; H10B 41/27; H10B 43/27

(52) U.S. Cl. CPC H10B 43/35; H10B 41/35; H10B 41/27; H10B 43/27

(57) ABSTRACT

A semiconductor device is provided. The semiconductor device includes a substrate including a memory cell region and a connection region, a plurality of gate electrodes in the memory cell region and arranged apart from one another in a vertical direction, the gate electrodes including a ground selection line and a plurality of word lines, a pair of gate stack separation insulation layers passing through the gate electrodes and extending in a first horizontal direction in the memory cell region and the connection region, and a pad structure including a plurality of pad layers in the connection region, connected to respective ones of the gate electrodes, arranged in a staircase shape in the first horizontal direction and in a second horizontal direction, the ground selection line including a plurality of ground selection line cut regions each being apart from edges of the pad layers in the second horizontal direction.

### CROSS-REFERENCE TO RELATED APPLICATION

This application is based on and claims priority under 35 U.S.C. § 119 to Korean Patent Application No. 10-2022-0077813, filed on Jun. 24, 2022, in the Korean Intellectual Property Office, the disclosure of which is incorporated by reference herein in its entirety.

### BACKGROUND

The inventive concepts relate to semiconductor devices and electronic systems including the same, and more particularly, to semiconductor devices including a vertical channel and electronic systems including the semiconductor device.

In an electronic system requiring the storage of data, semiconductor devices for storing massive data are needed. Therefore, a method of increasing the data storage capacity of semiconductor devices is being researched. For example, three-dimensional (3D) flash memory semiconductor devices each including memory cells arranged three-dimensionally, instead of memory cells arranged two-dimensionally, have been proposed as a method of increasing the data storage capacity of semiconductor devices.

### SUMMARY

The inventive concepts provide semiconductor devices, which may prevent or reduce the occurrence of a bridge defect in a process of forming a pad structure.

The inventive concepts provide electronic systems including the semiconductor device.

According to aspects of the inventive concepts, there is provided a semiconductor device including a substrate including a memory cell region and a connection region, a plurality of gate electrodes in the memory cell region of the substrate and arranged apart from one another in a vertical direction vertical to a top surface of the substrate, the plurality of gate electrodes including at least one ground selection line and a plurality of word lines arranged at a vertical level which is higher than the at least one ground selection line, a pair of gate stack separation insulation layers passing through the plurality of gate electrodes and extending in a first horizontal direction in the memory cell region and the connection region of the substrate, and a pad structure including a plurality of pad layers in the connection region of the substrate, connected to respective ones of the plurality of gate electrodes, arranged in a staircase shape in the first horizontal direction, and arranged in a staircase shape in a second horizontal direction vertical to the first horizontal direction, the at least one ground selection line including a plurality of ground selection line cut regions, and each of the plurality of ground selection line cut regions being arranged apart from edges of the plurality of pad layers in the second horizontal direction.

According to aspects of the inventive concepts, there is provided a semiconductor device including a substrate including a memory cell region and a connection region, a plurality of gate electrodes in the memory cell region of the substrate and arranged apart from one another in a vertical direction vertical to a top surface of the substrate, the plurality of gate electrodes including at least one ground selection line and a plurality of word lines arranged at a vertical level which is higher than the at least one ground selection line, and the at least one ground selection line including a plurality of ground selection line cut regions, a pair of gate stack separation insulation layers passing through the plurality of gate electrodes and extending in a first horizontal direction in the memory cell region and the connection region of the substrate, a plurality of channel structures arranged in the memory cell region of the substrate to pass through the plurality of gate electrodes and extend in the vertical direction, a pad structure including a plurality of pad layers in the connection region of the substrate and connected to respective ones of the plurality of gate electrodes, the pad structure including a first pad group including a plurality of first pad layers arranged in a staircase shape in the first horizontal direction, a second pad group including a plurality of second pad layers arranged in a staircase shape in the first horizontal direction, and a third pad group including a plurality of third pad layers arranged in a staircase shape in the first horizontal direction, a plurality of ground selection line insulation layers respectively filling the plurality of ground selection line cut regions of the at least one ground selection line, and a plurality of dummy stack opening portions between the pair of gate stack separation insulation layers to pass through the plurality of gate electrodes and extend in the first horizontal direction, and each of the plurality of ground selection line insulation layers vertically overlap the second pad group without vertically overlapping the first pad group.

According to aspects of the inventive concepts, there is provided an electronic system including a main substrate, a semiconductor device on the main substrate, and a controller electrically connected to the semiconductor device on the main substrate, the semiconductor device including a substrate including a memory cell region and a connection region, a plurality of gate electrodes in the memory cell region of the substrate and arranged apart from one another in a vertical direction vertical to a top surface of the substrate, the plurality of gate electrodes including at least one ground selection line and a plurality of word lines arranged at a vertical level which is higher than the at least one ground selection line, a pair of gate stack separation insulation layers passing through the plurality of gate electrodes and extending in a first horizontal direction in the memory cell region and the connection region of the substrate, and a pad structure including a plurality of pad layers in the connection region of the substrate, connected to respective ones of the plurality of gate electrodes, arranged in a staircase shape in the first horizontal direction, and arranged in a staircase shape in a second horizontal direction vertical to the first horizontal direction, the at least one ground selection line including a plurality of ground selection line cut regions, and each of the plurality of ground selection line cut regions being arranged apart from edges of the plurality of pad layers in the second horizontal direction.

### BRIEF DESCRIPTION OF THE DRAWINGS

Example embodiments will be more clearly understood from the following detailed description taken in conjunction with the accompanying drawings in which:

FIG. 1 is a block diagram illustrating a semiconductor device according to some example embodiments;

FIG. 2 is an equivalent circuit diagram of a memory cell array of a semiconductor device according to some example embodiments;

FIG. 3 is a perspective view illustrating a representative configuration of a semiconductor device according to some example embodiments;

FIG. 4 is a plan view illustrating the semiconductor device of FIG. 3;

FIG. 5 is a cross-sectional view taken along line A-A′ of FIG. 4;

FIG. 6 is a cross-sectional view taken along line B-B′ of FIG. 4;

FIG. 7 is a cross-sectional view taken along line C-C′ of FIG. 4;

FIG. 8 is a cross-sectional view taken along line D-D′ of FIG. 4;

FIG. 9 is a cross-sectional view taken along line E-E′ of FIG. 4;

FIG. 10 is a plan view with respect to a first vertical level LV1 of FIG. 5;

FIG. 11 is an enlarged view of a region CX1 of FIG. 5;

FIG. 12 is a cross-sectional view illustrating a channel structure according to some example embodiments;

FIG. 13 is a cross-sectional view illustrating a channel structure according to some example embodiments;

FIG. 14 is a plan view illustrating a semiconductor device according to some example embodiments;

FIG. 15 is a cross-sectional view taken along line C-C′ of FIG. 14;

FIG. 16 is a layout view illustrating a semiconductor device according to some example embodiments;

FIG. 17 is a cross-sectional view illustrating a semiconductor device according to some example embodiments;

FIGS. 18A to 21B are cross-sectional views illustrating a method of manufacturing a semiconductor device, according to some example embodiments; In detail, FIGS. 18A, 19A, 20A, and 21A are plan views based on a manufacturing process sequence, FIG. 18B is a cross-sectional view taken along line C-C′ of FIG. 18A, FIGS. 19B and 19C are cross-sectional views respectively taken along line C-C′ and line E-E′ of FIG. 19A, FIGS. 20B and 20C are cross-sectional views respectively taken along line A-A′ and line C-C′ of FIG. 20A, and FIG. 21B is a cross-sectional view taken along line C-C′ of FIG. 21A;

FIG. 22 is a diagram schematically illustrating a data storage system including a semiconductor device, according to some example embodiments;

FIG. 23 is a perspective view schematically illustrating a data storage system including a semiconductor device, according to some example embodiments; and

FIG. 24 is a cross-sectional view schematically illustrating semiconductor packages according to some example embodiments.

### DETAILED DESCRIPTION

Hereinafter, example embodiments will be described in detail with reference to the accompanying drawings.

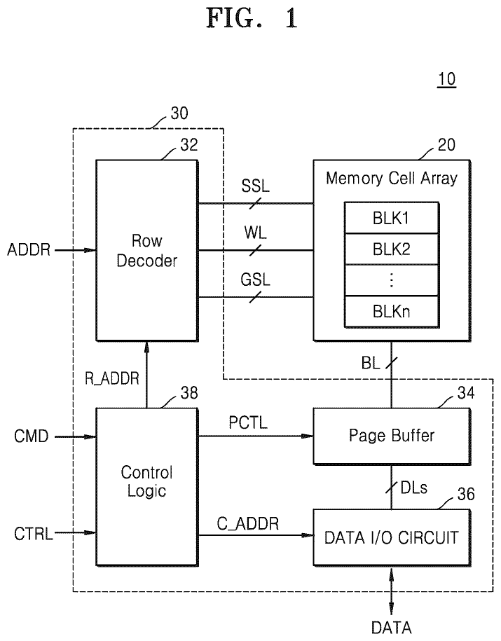

FIG. 1 is a block diagram illustrating a semiconductor device 10 according to some example embodiments.

Referring to FIG. 1, the semiconductor device 10 may include a memory cell array 20 and a peripheral circuit 30. The memory cell array 20 may include a plurality of memory cell blocks BLK1, BLK2, . . . , and BLKn. Each of the plurality of memory cell blocks BLK1, BLK2, . . . , and BLKn may include a plurality of memory cells. The memory cell blocks BLK1, BLK2, . . . , and BLKn may be connected to the peripheral circuit 30 through a bit line BL, a word line WL, a string selection line SSL, and a ground selection line GSL.

The peripheral circuit 30 may include a row decoder 32, a page buffer 34, a data input/output (I/O) circuit 36, and a control logic 38. Although not shown, the peripheral circuit 30 may further include an I/O interface, a column logic, a voltage generator, a pre-decoder, a temperature sensor, a command decoder, an address decoder, and/or an amplification circuit.

The memory cell array 20 may be connected to the page buffer 34 through the bit line BL and may be connected to the row decoder 32 through the word line WL, the string selection line SSL, and the ground selection line GSL. In the memory cell array 20, each of a plurality of memory cells included in the plurality of memory cell blocks BLK1, BLK2, . . . , and BLKn may be a flash memory cell. The memory cell array 20 may include a three-dimensional (3D) memory cell array. The 3D memory cell array may include a plurality of NAND strings, and each of the NAND strings may include a plurality of memory cells connected to a plurality of word lines WL, which are vertically stacked on a substrate.

The peripheral circuit 30 may receive an address ADDR, a command CMD, and a control signal CTRL from the outside of the semiconductor device 10 and may transfer and receive data DATA to and from a device outside the semiconductor device 10.

In response to the address ADDR from the outside, the row decoder 32 may select at least one memory cell block from among the plurality of memory cell blocks BLK1, BLK2, . . . , and BLKn and may select a word line WL, a string selection line SSL, and a ground selection line GSL of the selected memory cell block. The row decoder 32 may transfer a voltage, which is for performing a memory operation, to the word line WL of the selected memory cell block.

The page buffer 34 may be connected to the memory cell array 20 through the bit line BL. The page buffer 34 may operate as a write driver to apply a voltage based on the data DATA, which is to be stored in the memory cell array 20, to the bit line BL in a program operation, and in a read operation, the page buffer 34 may operate as a sense amplifier to sense the data DATA stored in the memory cell array 20. The page buffer 34 may operate based on a control signal PCTL provided from the control logic 38.

The data I/O circuit 36 may be connected to the page buffer 34 through data lines DLs. In the program operation, the data I/O circuit 36 may receive the data DATA from a memory controller (not shown) and may provide program data DATA to the page buffer 34, based on a column address C_ADDR provided from the control logic 38. In the read operation, the data I/O circuit 36 may provide the memory controller with read data DATA stored in the page buffer 34, based on the column address C_ADDR provided from the control logic 38.

The data I/O circuit 36 may transfer an input address or command to the control logic 38 or the row decoder 32. The peripheral circuit 30 may further include, for example, an electrostatic discharge (ESD) circuit and a pull-up/pull-down driver, which are not shown.

The control logic 38 may receive the command CMD and the control signal CTRL from the memory controller. The control logic 38 may provide a row address R_ADDR to the row decoder 32 and may provide the column address C_ADDR to the data I/O circuit 36. The control logic 38 may generate various internal control signals used in the semiconductor device 10 in response to the control signal CTRL. For example, the control logic 38 may adjust a voltage level provided to the word line WL and the bit line BL in performing a memory operation, such as a program operation or an erase operation.

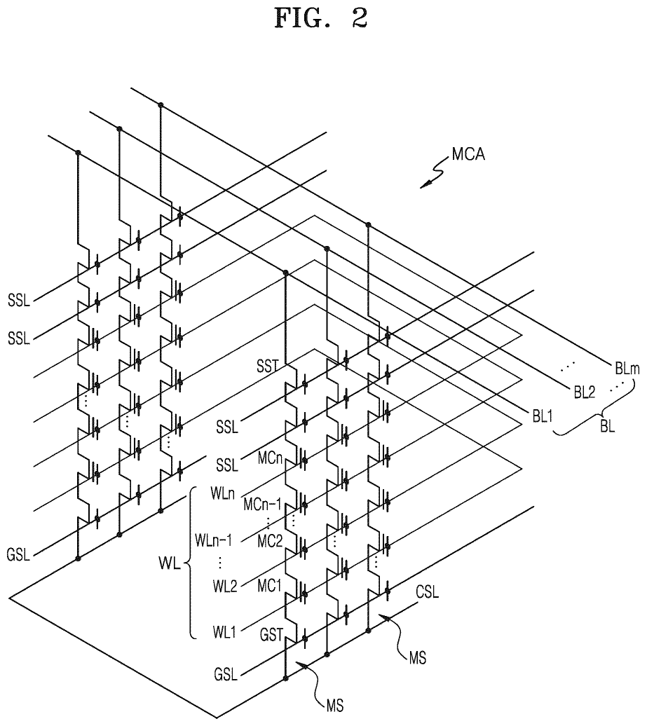

FIG. 2 is an equivalent circuit diagram of a memory cell array MCA of a semiconductor device 10 according to some example embodiments.

Referring to FIG. 2, the memory cell array MCA may include a plurality of memory cell strings MS. The memory cell array MCA may include a plurality of bit lines (BL) BL1, BL2, . . . , and BLm, a plurality of word lines (WL) WL1, WL2, . . . , WLn-1, and WLn, at least one string selection line SSL, at least one ground selection line GSL, and a common source line CSL. A plurality of memory cell strings MS may be arranged between the plurality of bit lines (BL) BL1, BL2, . . . , and BLm and the common source line CSL. In FIG. 2, some example embodiments where each of the plurality of memory cell strings MS includes two string selection lines SSL are illustrated, but the inventive concepts are not limited thereto. For example, each of the plurality of memory cell strings MS may include one string selection line SSL.

Each of the plurality of memory cell strings MS may include a string selection transistor SST, a ground selection transistor GST, and a plurality of memory cell transistors MC1, MC2, . . . , MCn-1, and MCn. A drain region of the string selection transistor SST may be connected to the plurality of bit lines (BL) BL1, BL2, . . . , and BLm, and a source region of the ground selection transistor GST may be connected to the common source line CSL. The common source line CSL may be a region, which is connected to a source region of each of a plurality of ground selection transistors GST in common.

The string selection transistor SST may be connected to the string selection line SSL, and the ground selection transistor GST may be connected to the ground selection line GSL. The plurality of memory cell transistors MC1, MC2, . . . , MCn-1, and MCn may be respectively connected to the plurality of word lines (WL) WL1, WL2, . . . , WLn-1, and WLn.

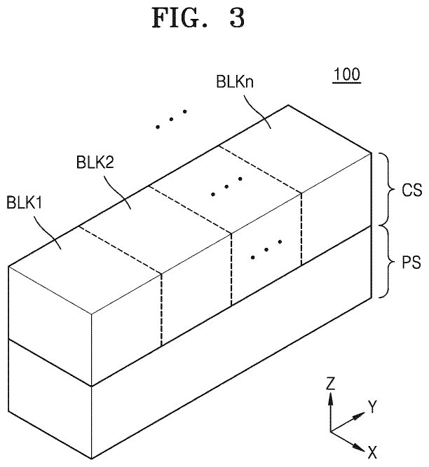

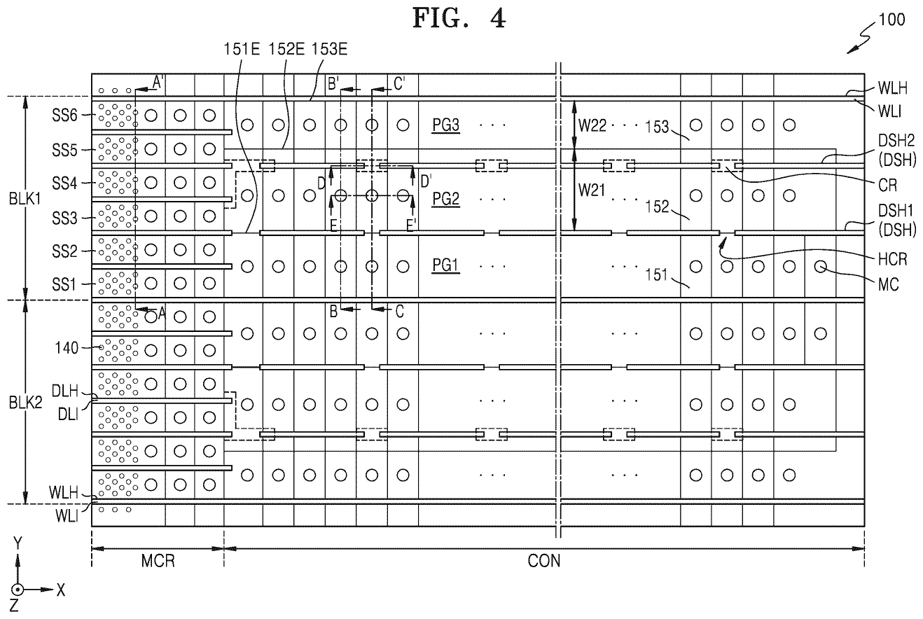

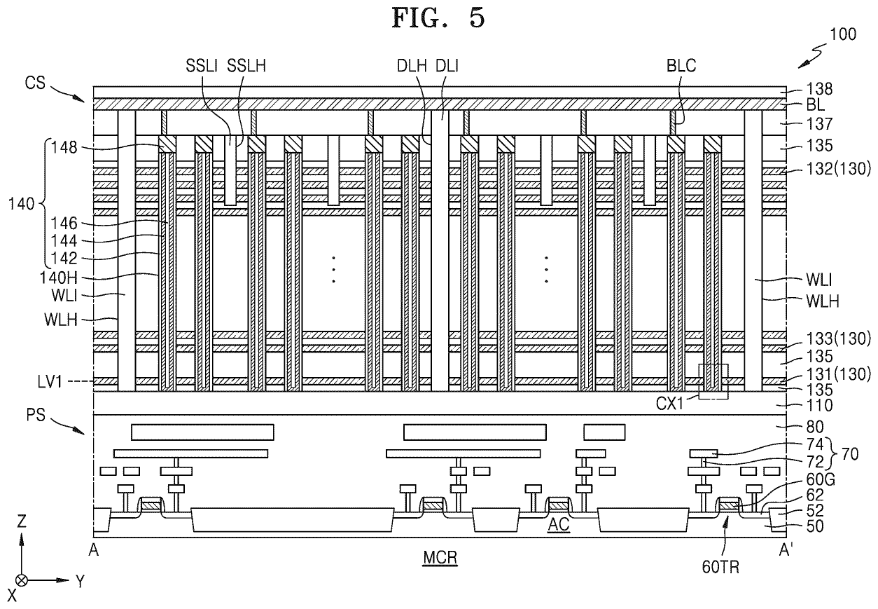

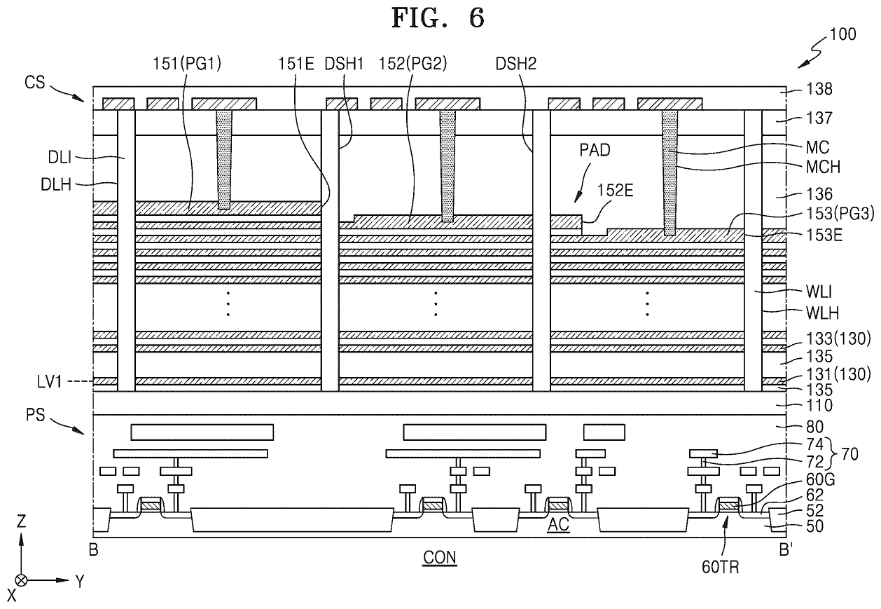

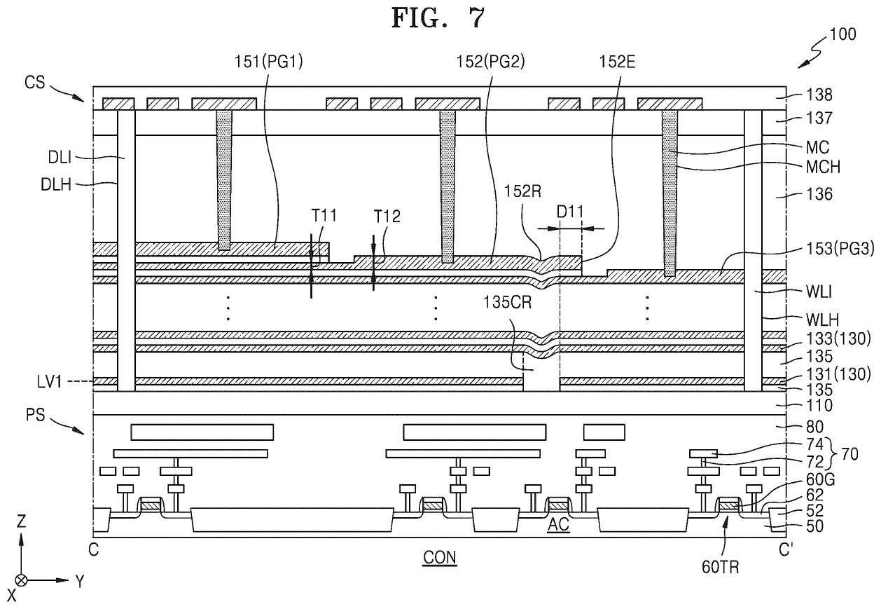

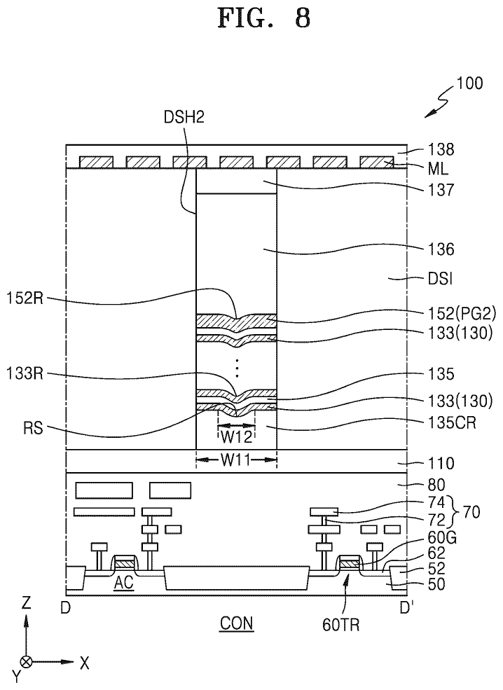

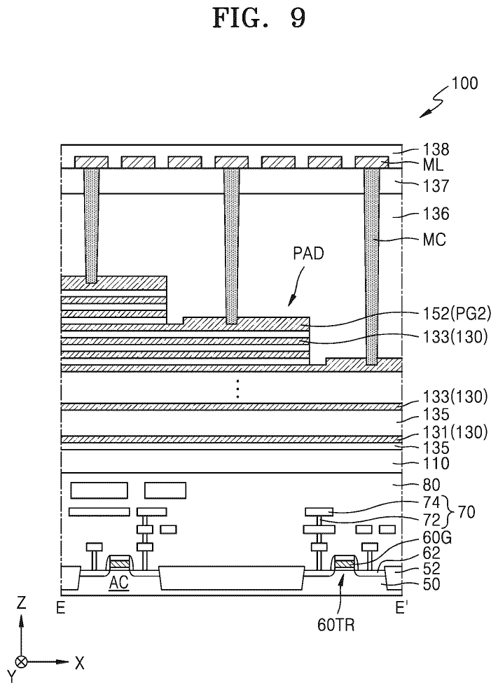

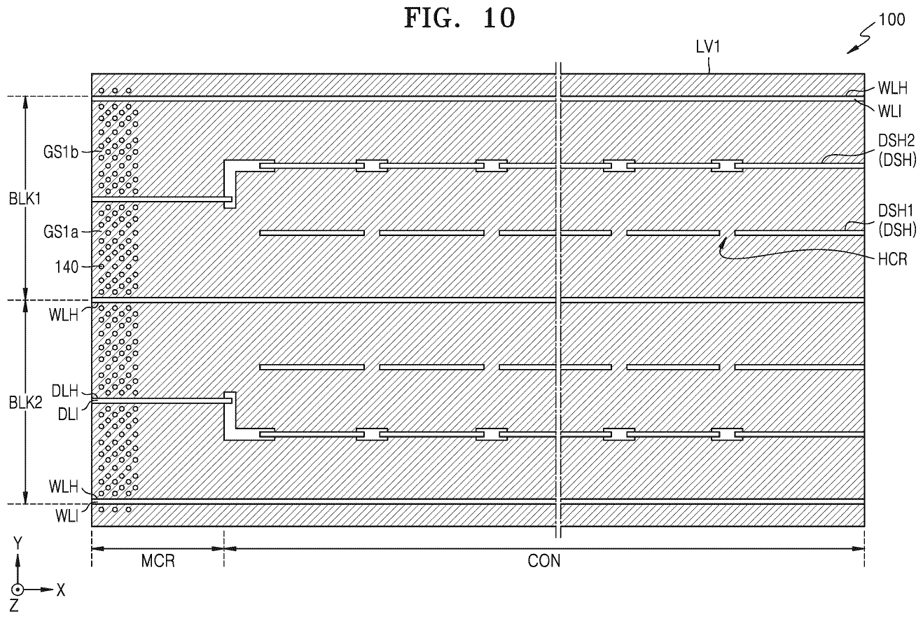

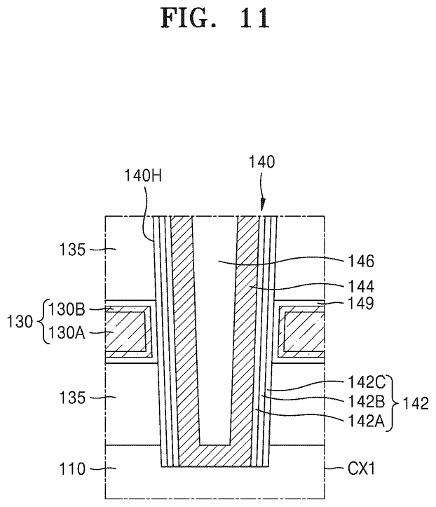

FIGS. 3 to 11 are diagrams for describing a semiconductor device 100 according to some example embodiments. In detail, FIG. 3 is a perspective view illustrating a representative configuration of a semiconductor device 100 according to some example embodiments, and FIG. 4 is a plan view illustrating the semiconductor device 100 of FIG. 3. FIG. 5 is a cross-sectional view taken along line A-A′ of FIG. 4, FIG. 6 is a cross-sectional view taken along line B-B′ of FIG. 4, FIG. 7 is a cross-sectional view taken along line C-C′ of FIG. 4, FIG. 8 is a cross-sectional view taken along line D-D′ of FIG. 4, and FIG. 9 is a cross-sectional view taken along line E-E′ of FIG. 4. FIG. 10 is a plan view with respect to a first vertical level LV1 of FIG. 5, and FIG. 11 is an enlarged view of a region CX1 of FIG. 5.

Referring to FIGS. 3 to 11, the semiconductor device 100 may include a cell array structure CS and a peripheral circuit structure PS, which overlap each other in a vertical direction Z. The cell array structure CS may include the memory cell array 20 described above with reference to FIG. 1, and the peripheral circuit structure PS may include the peripheral circuit 30 described above with reference to FIG. 1.

The cell array structure CS may include a plurality of memory cell blocks BLK1, BLK2, . . . , and BLKn. Each of the plurality of memory cell blocks BLK1, BLK2, . . . , and BLKn may include a plurality of memory cells, which are three-dimensionally arranged.

The peripheral circuit structure PS may include a peripheral circuit transistor 60TR and a peripheral circuit wiring structure 70, which are disposed on a substrate 50. The substrate 50 may include a memory cell region MCR and a connection region CON, which are one-dimensionally arranged. An active region AC may be defined by a device isolation layer 52 in the substrate 50, and a plurality of peripheral circuit transistors 60TR may be formed in the active region AC. The plurality of peripheral circuit transistors 60TR may each include a peripheral circuit gate 60G and a source/drain region 62 disposed at a portion of the substrate 50 at both sides of the peripheral circuit gate 60G.

The substrate 50 may include a semiconductor material, and for example, may include Group IV semiconductors, Group III-V compound semiconductors, and/or Group II-VI semiconductors. For example, the Group IV semiconductors may include silicon (Si), germanium (Ge), and/or silicon-germanium (SiGe). The substrate 50 may be provided as a bulk wafer or an epitaxial layer. In some example embodiments, the substrate 50 may include a silicon-on-insulator (SOI) substrate or a germanium-on-insulator (GeOI) substrate.

The peripheral circuit wiring structure 70 may include a plurality of peripheral circuit contacts 72 and a plurality of peripheral circuit wiring layers 74. An interlayer insulation layer 80 covering the peripheral circuit transistor 60TR and the peripheral circuit wiring structure 70 may be disposed on the substrate 50. A plurality of peripheral circuit wiring layers 74 may have a multi-layer structure including a plurality of metal layers arranged at different vertical levels.

A common source plate 110 may be disposed on the interlayer insulation layer 80. In some example embodiments, the common source plate 110 may function as a source region, which supplies a current to vertical memory cells formed in the cell array structure CS. The common source plate 110 may be disposed in the memory cell region MCR and the connection region CON of the substrate 50.

In some example embodiments, the common source plate 110 may include at least one of Si, Ge, SiGe, gallium arsenic (GaAs), indium gallium arsenic (InGaAs), aluminum gallium arsenic (AlGaAs), or a compound thereof. Also, the common source plate 110 may include a semiconductor doped with n-type impurities. Also, the common source plate 110 may have a crystalline structure including at least one structure selected from among a single crystalline structure, an amorphous structure, and a polycrystalline structure. In some example embodiments, the common source plate 110 may include polysilicon doped with n-type impurities.

A plurality of gate electrodes 130 and a plurality of mold insulation layers 135 may be alternately arranged in a vertical direction Z on the common source plate 110. The plurality of gate electrodes 130 may be arranged apart from one another in the vertical direction Z.

In some example embodiments, the plurality of gate electrodes 130 may correspond to at least one ground selection line GSL, a plurality of word lines (WL) WL1, WL2, . . . , WLn-1, and WLn, and at least one string selection line SSL, which configure a memory cell string MS (see FIG. 2). For example, a lowermost gate electrode 130 may function (and may be referred to) as the ground selection line GSL, three uppermost gate electrodes 130 may function as the string selection line SSL, and the other gate electrode 130 may function as the word line WL. Therefore, the memory cell string MS including the ground selection transistor GST, the string selection transistor SST, and memory cell transistors MC1, MC2, . . . , MCn-1, and MCn therebetween may be provided. Here, the lowermost gate electrode 130 functioning as the ground selection line GSL may be referred to as a first gate electrode 131, the three uppermost gate electrodes 130 functioning as the string selection line SSL may be referred to as a second gate electrode 132, and the other gate electrode 130 functioning as the word line WL may be referred to as a third gate electrode 133.

In some example embodiments, a mold insulation layer 135 between the first gate electrode 131 (as labeled above, the lowermost gate electrode 130 functioning as the ground selection line GSL) and the third gate electrode 133 (i.e., a gate electrode 130 disposed immediately on the lowermost gate electrode 130 among gate electrodes 130 functioning as the word line WL) may have a vertical-direction thickness, which is greater than the other mold insulation layer 135.

In some example embodiments, two lowermost gate electrodes 130 may function as the ground selection line GSL, and two first gate electrodes 131 may be arranged apart from each other in a vertical direction. In this case, the mold insulation layer 135 between an upper first gate electrode 131 and the lowermost third gate electrode 133 may have a vertical-direction thickness, which is greater than the other mold insulation layer 135.

In some example embodiments, at least one of the gate electrodes 130 may function as a dummy word line. For example, at least one additional gate electrode 130 may be disposed between at least one first gate electrode 131 functioning as the ground selection line GSL and the common source plate 110, at least one additional gate electrode 130 may be disposed between at least one first gate electrode 131 functioning as the ground selection line GSL and the lowermost third gate electrode 133 functioning as the word line WL, or at least one additional gate electrode 130 may be disposed between the uppermost third gate electrode 133 functioning as the word line WL and the lowermost second gate electrode 132 functioning as the string selection line SSL.

As illustrated in FIG. 11, the gate electrode 130 may include a buried conductive layer 130A and a conductive barrier layer 130B surrounding a top surface, a bottom surface, and a side surface of the buried conductive layer 130A. For example, the buried conductive layer 130A may include metal, such as tungsten, nickel, or tantalum, metal silicide such as tungsten silicide, nickel silicide, cobalt silicide, or tantalum silicide, doped polysilicon, or a combination thereof. In some example embodiments, the conductive barrier layer 130B may include titanium nitride, tantalum nitride, tungsten nitride, or a combination thereof. In some example embodiments, a dielectric liner (not shown) may be further provided between the conductive barrier layer 130B and the mold insulation layer 135, and the dielectric liner may include a high-k dielectric material, such as aluminum oxide.

A plurality of channel structures 140 may pass through a plurality of gate electrodes 130 and a plurality of mold insulation layers 135 and may extend in a vertical direction (a Z direction) from a top surface of the common source plate 110, in the memory cell region MCR. The plurality of channel structures 140 may be arranged apart from one another by a certain interval in a first horizontal direction X, a second horizontal direction Y, and a third horizontal direction (for example, a diagonal direction, or a direction not parallel to either of the first horizontal direction X or the second horizontal direction Y). The plurality of channel structures 140 may be arranged in a zigzag shape or a staggered shape.

Each of the plurality of channel structures 140 may be disposed in a channel hole 140H in the memory cell region MCR. Each of the plurality of channel structures 140 may include a gate insulation layer 142, a channel layer 144, a buried insulation layer 146, and a conductive plug 148. The gate insulation layer 142 and the channel layer 144 may be sequentially arranged on a sidewall of the channel hole 140H. For example, the gate insulation layer 142 may be conformally disposed on the sidewall of the channel hole 140H, and the channel layer 144 may be conformally disposed on the sidewall and a bottom portion of the channel hole 140H. The channel layer 144 may be disposed to contact a top surface of the common source plate 110 at the bottom portion of the channel hole 140H. The buried insulation layer 146 filling a residual space of the channel hole 140H may be disposed on the channel layer 144. The conductive plug 148 which contacts the channel layer 144 and plugs an entrance of the channel hole 140H may be disposed at an upper portion of the channel hole 140H. In some example embodiments, the buried insulation layer 146 may be omitted, and the channel layer 144 may be formed in a pillar shape, which fills a residual portion of the channel hole 140H.

As illustrated in FIG. 11, the gate insulation layer 142 may have a structure including a tunneling dielectric layer 142A, a charge storage layer 142B, and a blocking dielectric layer 142C, which are sequentially arranged on an outer sidewall of the channel layer 144. A relative thickness of the tunneling dielectric layer 142A, the charge storage layer 142B, and the blocking dielectric layer 142C, each configuring the gate insulation layer 142, is not limited to the illustration of FIG. 11 and may be variously modified.

The tunneling dielectric layer 142A may include silicon oxide, hafnium oxide, aluminum oxide, zirconium oxide, and/or tantalum oxide. The charge storage layer 142B may be a region for storing electrons, which pass through the tunneling dielectric layer 142A from the channel layer 144, and may include silicon nitride, boron nitride, silicon boron nitride, and/or impurity-doped polysilicon. The blocking dielectric layer 142C may include silicon oxide, silicon nitride, and/or a metal oxide which is greater in dielectric constant than silicon oxide. The metal oxide may include, for example, hafnium oxide, aluminum oxide, zirconium oxide, tantalum oxide, or a combination thereof.

Bit lines BL may be apart from one another and may extend in the second horizontal direction Y, and moreover, may be electrically connected to the channel structure 140 by a bit line contact BLC.

As illustrated in FIG. 4, a plurality of gate stack separation opening portions WLH may extend in the first horizontal direction X parallel to the top surface of the common source plate 110, on the common source plate 110. A plurality of gate electrodes 130 disposed between a pair of gate stack separation opening portions WLH may configure one block. For example, a first block BLK1 and a second block BLK2 is illustrated in FIG. 4.

A gate stack separation insulation layer WLI filling an inner portion of the gate stack separation opening portion WLH may be disposed on the common source plate 110. The gate stack separation insulation layer WLI may include silicon oxide, silicon nitride, SiON, SiOCN, SiCN, or a combination thereof.

As illustrated in FIGS. 4 and 5, in a plan view, a plurality of gate electrodes 130 may be divided into two portions by a dummy stack separation opening portion DLH, in one block in the memory cell region MCR. For example, the dummy stack separation opening portion DLH may divide a plurality of gate electrodes 130, corresponding to the first block BLK1, into two portions in the second horizontal direction Y, and a dummy stack separation insulation layer DLI may be disposed in the dummy stack separation opening portion DLH. The dummy stack separation insulation layer DLI may extend over a total height of the plurality of gate electrodes 130 in the vertical direction Z and may extend in the first horizontal direction X between a pair of gate stack separation opening portions WLH in a plan view.

Three uppermost second gate electrodes 132 in one block may be divided into six portions by a string separation opening portion SSLH, in a plan view. For example, two string separation opening portions SSLH may be disposed between one gate stack separation opening portion WLH and a dummy stack separation opening portion DLH adjacent thereto, and a string separation insulation layer SSLI may be disposed in the string separation opening portion SSLH. In this manner, the second gate electrode 132 may include first to sixth string selection line segments SS1 to SS6 sequentially arranged in the second horizontal direction Y, in one block. The first to sixth string selection line segments SS1 to SS6 may be electrically insulated from one another by the string separation insulation layer SSLI and may configure the string selection line SSL described above with reference to FIG. 2. In FIG. 4, some example embodiments where one block includes six string selection line segments are illustrated, but in some example embodiments, one block may include two, three, four, or eight string selection line segments and the number of second gate electrodes 132 arranged in the vertical direction Z may be appropriately changed based on the number of string selection line segments.

The plurality of gate electrodes 130 may configure a pad portion PAD in the connection region CON. In the connection region CON, the plurality of gate electrodes 130 may extend to have a length, which decreases progressively in the first horizontal direction X or the second horizontal direction Y as the plurality of gate electrodes 130 are farther away from a top surface of the common source plate 110. The pad portion PAD may denote portions of the gate electrodes 130 arranged in a staircase shape. The pad portion PAD may have a staircase shape in both of the first horizontal direction X and the second horizontal direction Y. A cover insulation layer 136 may be disposed on the plurality of gate electrodes 130 configuring the pad portion PAD.

In some example embodiments, the pad portion PAD may include a first pad group PG1, a second pad group PG2, and a third pad group PG3, which are sequentially arranged in the second horizontal direction Y in one block. For example, the first pad group PG1 may include a plurality of first pad layers 151 arranged in a staircase shape in the first horizontal direction X, the second pad group PG2 may include a plurality of second pad layers 152 arranged in a staircase shape in the first horizontal direction X, and the third pad group PG3 may include a plurality of third pad layers 153 arranged in a staircase shape in the first horizontal direction X.

One first pad layer 151 included in the first pad group PG1, one second pad layer 152 included in the second pad group PG2, and one third pad layer 153 included in the third pad group PG3 may be sequentially arranged in the second horizontal direction Y and may form a staircase shape in the second horizontal direction Y. For example, a top surface of one second pad layer 152 may be at a vertical level, which is lower than a top surface of one first pad layer 151, and a top surface of one third pad layer 153 may be at a vertical level, which is lower than a top surface of one second pad layer 152.

As illustrated in FIG. 7, each of the plurality of gate electrodes 130 may have a first thickness T11, and each of the plurality of first pad layers 151, the plurality of second pad layers 152, and the plurality of third pad layers 153 may have a second thickness T12, which is greater than the first thickness T11 in the vertical direction Z. For example, each of the plurality of first pad layers 151, the plurality of second pad layers 152, and the plurality of third pad layers 153 may include a top surface arranged at a level, which is higher than a top surface of each of the plurality of gate electrodes 130 connected thereto, and may be referred to as a raised pad.

The plurality of gate electrodes 130 may include a plurality of dummy stack opening portions DSH, which extend in the first horizontal direction X, in the connection region CON. The plurality of dummy stack opening portions DSH may be arranged on a straight line to extend in the first horizontal direction X, and a connection portion HCR of each of the plurality of gate electrodes 130 may be defined between two adjacent dummy stack opening portions DSH. For example, the connection portion HCR may denote a portion of each of the plurality of gate electrodes 130 disposed between two dummy stack opening portions DSH adjacent to each other in the first horizontal direction X. A dummy stack insulation layer DSI may be disposed in the plurality of dummy stack opening portions DSH. The dummy stack insulation layer DSI may pass through the plurality of gate electrodes 130 and the cover insulation layer 136 and may extend in the vertical direction Z.

As illustrated in FIG. 4, the plurality of dummy stack opening portions DSH may include a plurality of first dummy stack opening portions DSH1 disposed between the first pad group PG1 and the second pad group PG2 and a plurality of second dummy stack opening portions DSH2 vertically overlapping the second pad group PG2. For example, in a plan view, the plurality of first dummy stack opening portions DSH1 may be arranged in the first horizontal direction X at a boundary between the first pad group PG1 and the second pad group PG2, and each of the plurality of first dummy stack opening portions DSH1 may extend by a certain length in the first horizontal direction X. The plurality of second dummy stack opening portions DSH2 may be arranged in the first horizontal direction X at a position vertically overlapping the second pad group PG2, and each of the plurality of second dummy stack opening portions DSH2 may extend by a certain length in the first horizontal direction X.

As illustrated in FIG. 10, the plurality of first dummy stack opening portions DSH1 and the plurality of second dummy stack opening portions DSH2 may pass through a first gate electrode 131 (i.e., a lowermost gate electrode 130 configuring a ground selection line GSL). Each of a plurality of ground selection line cut regions CR may be disposed between two adjacent second dummy stack opening portions DSH2 of the plurality of second dummy stack opening portions DSH2. The plurality of ground selection line cut regions CR may be a region, which is formed by removing a portion of the first gate electrode 131 disposed between two adjacent second dummy stack opening portions DSH2 of the plurality of second dummy stack opening portions DSH2.

As illustrated in FIG. 10, the plurality of ground selection line cut regions CR may be disposed between two adjacent second dummy stack opening portions DSH2, and the dummy stack separation opening portion DLH may pass through the first gate electrode 131 (i.e., the lowermost gate electrode 130 configuring the ground selection line GSL) and may extend in the first horizontal direction X, in the memory cell region MCR. Therefore, the first gate electrode 131 (i.e., the lowermost gate electrode 130 configuring the ground selection line GSL) may be divided into two first gate electrodes arranged apart from each other in a lateral direction, in one block. The two first gate electrodes arranged apart from each other in the lateral direction may be referred to as a first ground selection line GSLa and a second ground selection line GSLb. One block may include a first ground selection line GSLa and a second ground selection line GSLb, which are spaced apart from each other in the lateral direction, and may be configured so that each of the first ground selection line GSLa and the second ground selection line GSLb operates independently, and thus, a reduction in performance in a read operation of the semiconductor device 100 may be prevented or reduced.

In some example embodiments, as illustrated in FIG. 10, a shape of each of first and second ground selection lines GSLa and GSLb of the first block BLK1 may have a symmetrical structure with respect to a shape of each of first and second ground selection lines GSLa and GSLb of the second block BLK2. For example, the shape of the first and second ground selection lines GSLa and GSLb of the first block BLK1 and of the first and second ground selection lines GSLa and GSLb of the second block BLK2 may be mirrored based on the boundary between the first and second blocks BLK1 and BLK2.

A ground selection line insulation layer 135CR may be disposed in each of the plurality of ground selection line cut regions CR. In some example embodiments, the ground selection line insulation layer 135CR may include the same material as a material included in the mold insulation layer 135. In some example embodiments, the ground selection line insulation layer 135CR may include a material which differs from the material included in the mold insulation layer 135. In some example embodiments, the ground selection line insulation layer 135CR may be formed by filling an insulation material, having good step coverage, into each of the plurality of ground selection line cut regions CR.

In some example embodiments, as illustrated in FIG. 8, the ground selection line insulation layer 135CR may have a top profile, which is recessed downward. For example, the ground selection line insulation layer 135CR may include a recessed top surface RS, and the recessed top surface RS of the ground selection line insulation layer 135CR may have a top level, which lowers progressively toward a center of the ground selection line insulation layer 135CR from a peripheral portion of the ground selection line insulation layer 135CR.

A lowermost third gate electrode 133 (i.e., a lowermost gate electrode 130 configuring a word line WL) disposed on the ground selection line insulation layer 135CR may include a bottom surface of a curved surface, contacting the recessed top surface RS of the ground selection line insulation layer 135CR. At least one of a plurality of third gate electrodes 133, which vertically overlap the ground selection line cut region CR and are arranged at a level which is higher than the ground selection line insulation layer 135CR, may include at least one bending portion 133R. The bending portion 133R may have a curved shape conforming to a shape of the recessed top surface RS of the ground selection line insulation layer 135CR or a portion of the third gate electrode 133 protruding or bent downward. Also, as illustrated in FIG. 8, at least a portion of a second pad layer 152 vertically overlapping the ground selection line insulation layer 135CR among the plurality of second pad layers 152 of the second pad group PG2 may include a bending portion 152R. The bending portion 152R may have a curved shape conforming to a shape of the recessed top surface RS of the ground selection line insulation layer 135CR or a portion of the third gate electrode 133 protruding or bent downward.

The ground selection line cut region CR may be disposed to vertically overlap the second pad group PG2, and in a plan view, the ground selection line cut region CR may be disposed in the second pad group PG2 not to vertically overlap an edge 152E of each of the plurality of second pad layers 152. The ground selection line cut region CR may be arranged apart from the edge 152E of each of the plurality of second pad layers 152 by a first distance D11 in the second horizontal direction Y.

As illustrated in FIG. 8, the ground selection line cut region CR may have a first width W11 in the first horizontal direction X, and the bending portion 133R may have a second width W12, which is less than the first width W11 in the first horizontal direction X. As the second width W12 of the bending portion 133R is less than the first width W11 of the ground selection line cut region CR, the edge 152E of each of the plurality of second pad layers 152 may be disposed apart from the bending portion 133R in the second horizontal direction Y and may be disposed at a position, which does not vertically overlap the bending portion 133R. Also, the bending portion 152R of the second pad layer 152 may be disposed apart from the edge 152E of the second pad layer 152 in the second horizontal direction Y.

In some example embodiments, each of the plurality of second pad layers 152 of the second pad group PG2 may have a third width W21 in the second horizontal direction Y, and each of the plurality of third pad layers 153 of the third pad group PG3 may have a fourth width W22, which is less than the third width W21 in the second horizontal direction Y.

Although not shown, a plurality of dummy channel structures (not shown), which pass through the plurality of gate electrodes 130 and the plurality of mold insulation layers 135 from the top surface of the common source plate 110 and extend in the vertical direction Z, may be further formed in the connection region CON. The dummy channel structure may be formed for preventing (or reducing) leaning or bending of the gate electrodes 130 in a process of manufacturing the semiconductor device 100 and securing structural stability. Each of the plurality of dummy channel structures may have a structure and a shape, which are similar to those of the plurality of channel structures 140. A first upper insulation layer 137 may be disposed on an uppermost mold insulation layer 135 and a cover insulation layer 136.

A cell contact plug MC, which passes through the first upper insulation layer 137 and the cover insulation layer 136 and is connected to the gate electrode 130, may be disposed in the connection region CON. The cell contact plug MC may be disposed in a cell contact hole MCH passing through the first upper insulation layer 137 and the cover insulation layer 136. A wiring line ML connected to the cell contact plug MC may be disposed on the first upper insulation layer 137. A second upper insulation layer 138 covering the wiring line ML and the bit line BL may be disposed on the first upper insulation layer 137.

According to some example embodiments, the ground selection line cut region CR may not overlap the edges 152E of the plurality of second pad layers 152 of the second pad group PG2 and may be disposed apart from the edge 152E thereof in the second horizontal direction Y. Also, the ground selection line cut region CR may be disposed not to overlap edges 151E of the plurality of first pad layers 151 of the first pad group PG1. Therefore, a pad layer bridge defect, which occurs when the ground selection line cut region CR is disposed at a position vertically overlapping the edge 151E of each of the plurality of first pad layers 151 and the edge 152E of each of the plurality of second pad layers 152, and thus occurs when the first and second pad layers 151 and 152 are not sufficiently detached from another first and second pad layers 151 and 152 thereunder due to a bending portion, may be avoided or reduced.

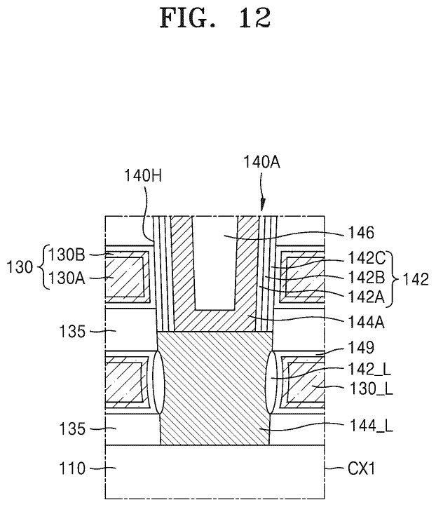

FIG. 12 is a cross-sectional view illustrating a channel structure 140A according to some example embodiments.

Referring to FIG. 12, the channel structure 140A may include a gate insulation layer 142, a channel layer 144A, a buried insulation layer 146, and a conductive plug 148 (not shown in FIG. 12) and may further include a contact semiconductor layer 144_L and a bottom insulation layer 142_L, which are disposed at a bottom portion of a channel hole 140H. The channel layer 144A may not directly contact a common source plate 110 and may be electrically connected to the common source plate 110 through the contact semiconductor layer 144_L. In some example embodiments, the contact semiconductor layer 144_L may include a silicon layer, which is formed by a selective epitaxy growth (SEG) process by using the common source plate 110, disposed at the bottom portion of the channel hole 140H, as a seed layer.

The bottom insulation layer 142_L may be disposed between a lowermost gate electrode 130_L and the contact semiconductor layer 144_L. In some example embodiments, the bottom insulation layer 142_L may include silicon oxide, and for example, may be formed by performing an oxidation process on a portion of a sidewall of the bottom insulation layer 142_L. The bottom insulating layer 142_L may have an oval shape and may completely separate (e.g., physically and/or electrically) the lowermost gate electrode 130_L and the contact semiconductor layer 144_L.

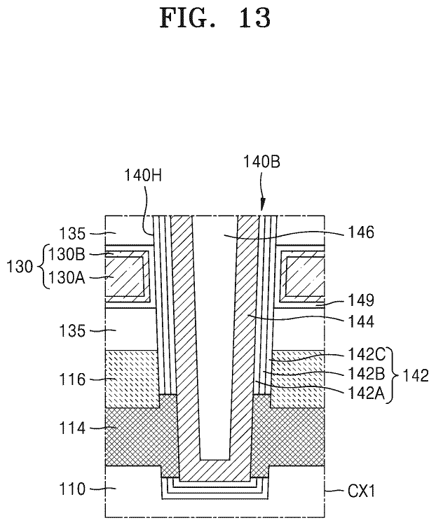

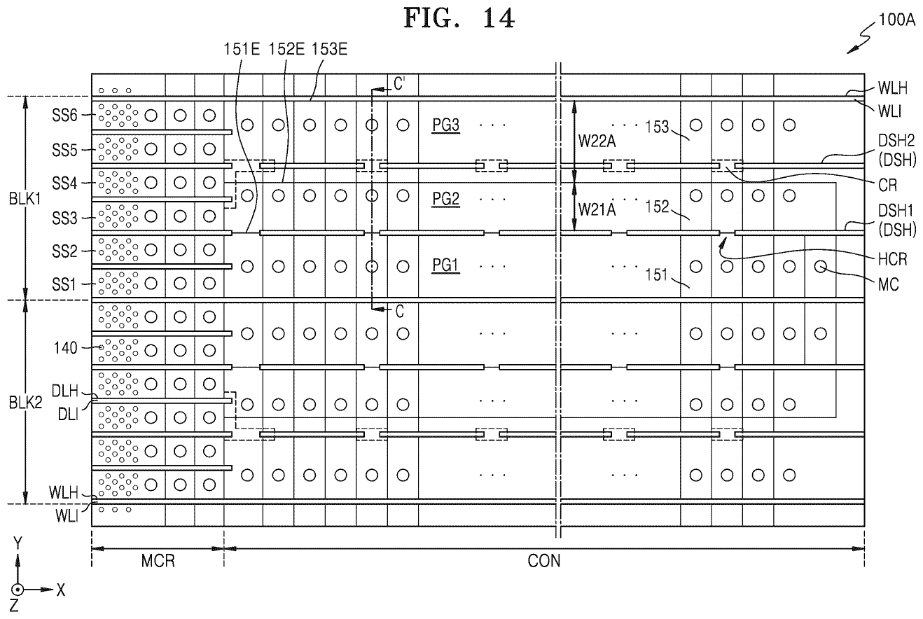

FIG. 13 is a cross-sectional view illustrating a channel structure 140B according to some example embodiments.

Referring to FIG. 13, in a memory cell region MCR, a horizontal semiconductor layer 114 and a supporting layer 116 may be sequentially stacked on a top surface of a common source plate 110, and a mold insulation layer 135 may be disposed on the supporting layer 116.

In some example embodiments, the horizontal semiconductor layer 114 may include impurity-doped polysilicon or impurity-undoped polysilicon. The horizontal semiconductor layer 114 may function as a portion of a common source region, which connects the common source plate 110 to the channel layer 144. For example, the supporting layer 116 may include doped or undoped polysilicon. The supporting layer 116 may function as a supporting layer for preventing (or reducing) leaning or bending of a mold stack in a process of removing a sacrificial material layer (not shown) for forming the horizontal semiconductor layer 114.

The channel structure 140B may include a gate insulation layer 142, a channel layer 144, a buried insulation layer 146, and a conductive plug 148. As illustrated in FIG. 13, the gate insulation layer 142 may be disposed on an inner wall and a bottom portion of a channel hole 140H. A bottom surface of the channel layer 144 may be disposed on the gate insulation layer 142 and may not directly contact the common source plate 110, and a bottom sidewall of the channel layer 144 may be surrounded by the horizontal semiconductor layer 114.

In some example embodiments, the horizontal semiconductor layer 114 may have end portions overlapping the supporting layer 116 and the common source plate 110 in a horizontal direction, and replacing and conforming to the thickness of the insulating layer 142 in the horizontal direction.

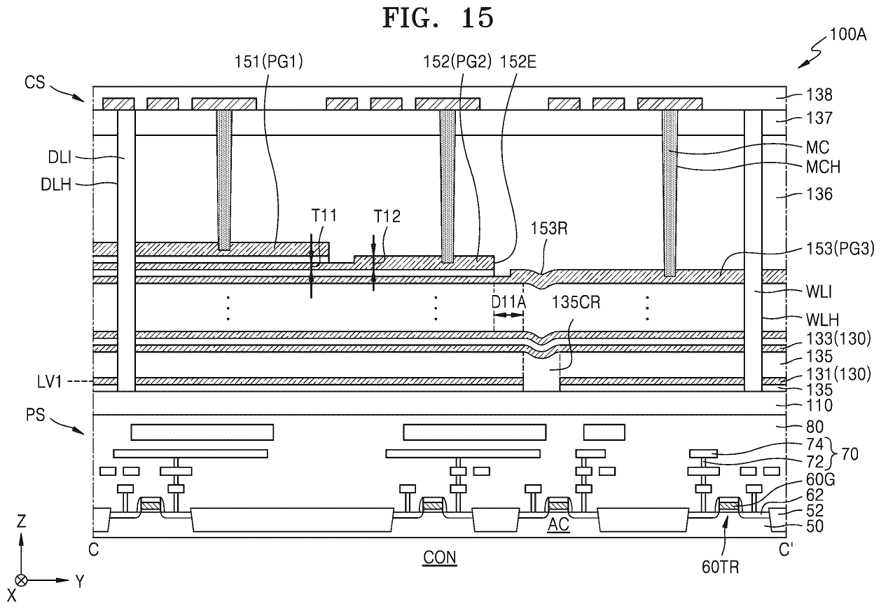

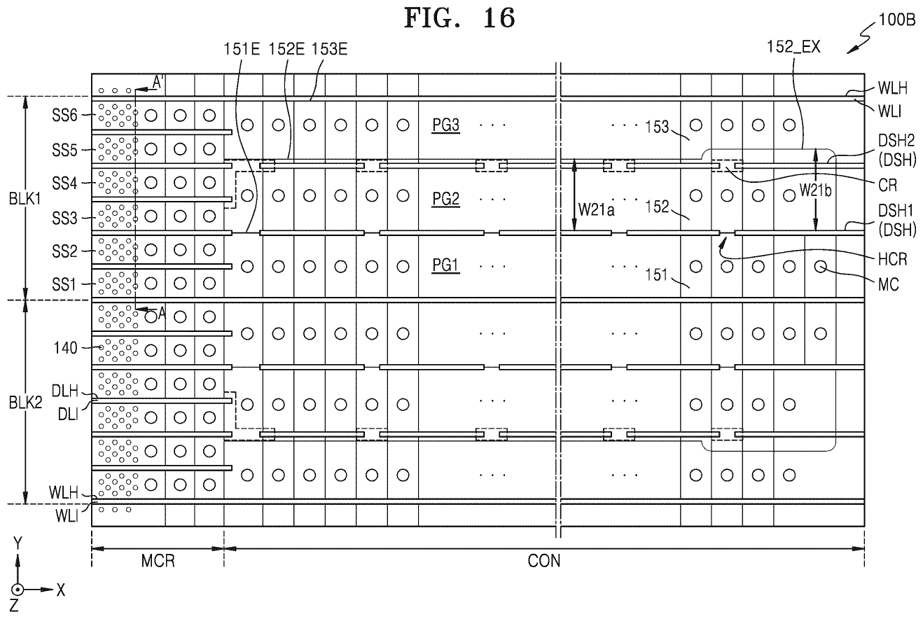

FIG. 14 is a plan view illustrating a semiconductor device 100A according to some example embodiments. FIG. 15 is a cross-sectional view taken along line C-C′ of FIG. 14.

Referring to FIGS. 14 and 15, a second pad group PG2 may not vertically overlap a second dummy stack opening portion DSH2 and a ground selection line cut region CR, and a third pad group PG3 may be disposed to vertically overlap the second dummy stack opening portion DSH2 and the ground selection line cut region CR. The ground selection line cut region CR may be disposed to vertically overlap the third pad group PG3, and in a plan view, the ground selection line cut region CR may be disposed in the third pad group PG3 not to vertically overlap an edge 152E of each of a plurality of second pad layers 152 and an edge 153E of each of a plurality of third pad layers 153. The ground selection line cut region CR may be arranged apart from the edge 152E of each of the plurality of second pad layers 152 by a first distance D11A in a second horizontal direction Y.

At least a portion of a third pad layer 153 vertically overlapping a ground selection line insulation layer 135CR among a plurality of third pad layers 153 of the third pad group PG3 may include a bending portion 153R.

In some example embodiments, each of the plurality of second pad layers 152 of the second pad group PG2 may have a third width W21A in the second horizontal direction Y, and each of the plurality of third pad layers 153 of the third pad group PG3 may have a fourth width W22A, which is greater than the third width W21A in the second horizontal direction Y.

According to some example embodiments, the ground selection line cut region CR may not overlap the edges 152E of the plurality of second pad layers 152 of the second pad group PG2 and may be disposed apart from the edge 152E thereof in the second horizontal direction Y. Also, the ground selection line cut region CR may be disposed not to overlap edges 151E of the plurality of first pad layers 151 of the first pad group PG1. Therefore, a pad layer bridge defect, which occurs when the ground selection line cut region CR is disposed at a position vertically overlapping the edge 151E of each of the plurality of first pad layers 151 and the edge 152E of each of the plurality of second pad layers 152, and thus occurs when the first and second pad layers 151 and 152 are not sufficiently detached from another first and second pad layers 151 and 152 thereunder due to a bending portion, may be avoided.

FIG. 16 is a layout view illustrating a semiconductor device 100B according to some example embodiments.

Referring to FIG. 16, a second pad group PG2 may include a plurality of second pad layers 152, and in a plan view, an edge 152E of each of the plurality of second pad layers 152 may include an extension portion 152_EX, which extends in a lateral direction. In some example embodiments, the extension portion 152_EX may be disposed in a portion of a connection region CON relatively apart from (e.g., spaced apart from, not adjacent to) a memory cell region MCR, and for example, a portion of a second pad layer 152 corresponding to the extension portion 152_EX may be disposed at a vertical level which is relatively close to a ground selection line insulation layer 135CR. For example, the portion of the second pad layer 152 corresponding to the extension portion 152_EX may be disposed to be connected to a third gate electrode 133 disposed close to a first gate electrode 131 among third gate electrodes 133 corresponding to a word line WL.

The extension portion 152_EX of the second pad layer 152 may be formed to vertically overlap a ground selection line cut region CR, and in a plan view, the ground selection line cut region CR may be disposed in the extension portion 152_EX of the second pad layer 152. Therefore, an edge 152E of the extension portion 152_EX may be disposed apart from the ground selection line cut region CR in a second horizontal direction Y.

According to some example embodiments, a plurality of second pad layers 152 may have a first width W21a in the second horizontal direction Y, and the extension portion 152_EX of each of the plurality of second pad layers 152 may have a second width W21b, which is greater than the first width W21a in the second horizontal direction Y.

According to some example embodiments, the ground selection line cut region CR may not overlap the edges 152E of the plurality of second pad layers 152 of the second pad group PG2 and may be disposed apart from the edge 152E thereof in the second horizontal direction Y. Therefore, a pad layer bridge defect, which occurs when the ground selection line cut region CR is disposed at a position vertically overlapping the edge 151E of each of the plurality of first pad layers 151 and the edge 152E of each of the plurality of second pad layers 152, and thus occurs when the first and second pad layers 151 and 152 are not sufficiently detached from another first and second pad layers 151 and 152 thereunder due to a bending portion, may be avoided or reduced.

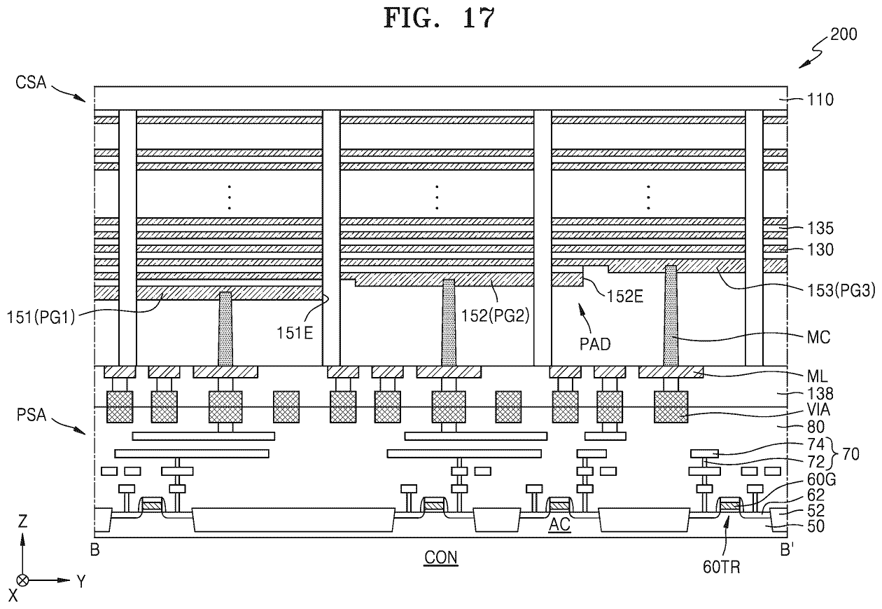

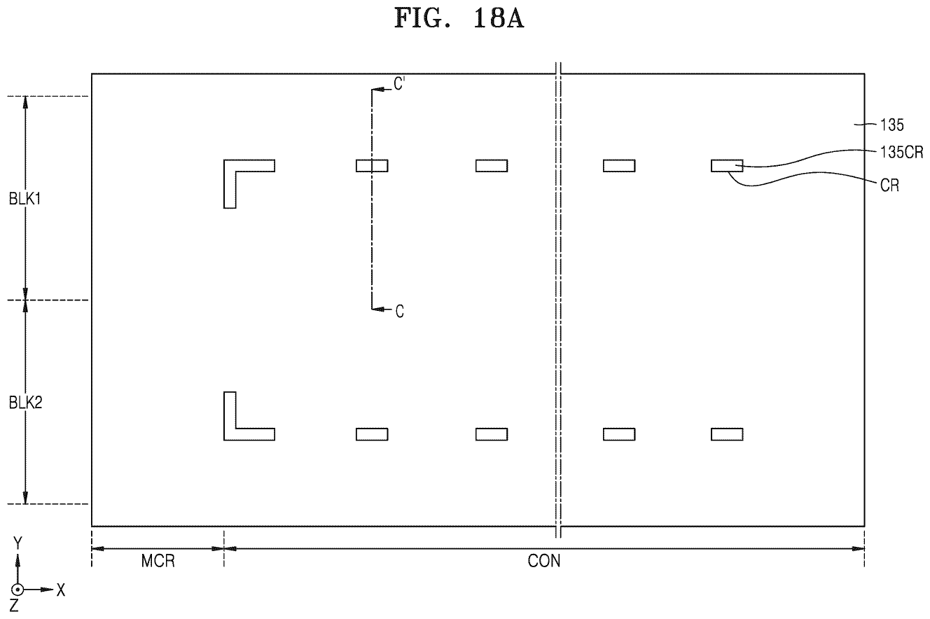

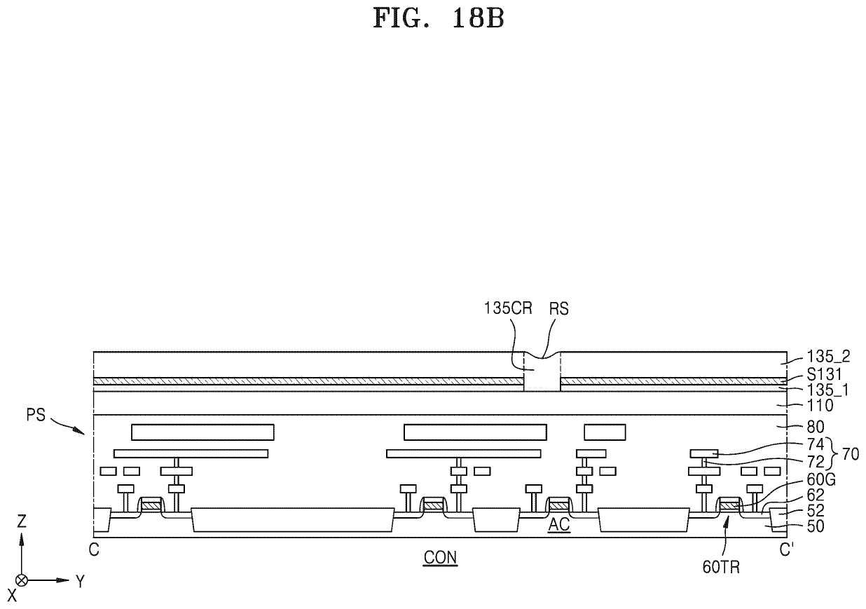

FIG. 17 is a cross-sectional view illustrating a semiconductor device 200 according to some example embodiments.

Referring to FIG. 17, the semiconductor device 200 may have a chip to chip (C2C) structure. The C2C structure may denote that an upper chip including a cell array structure CSA is manufactured on a first wafer and a lower chip including a peripheral circuit structure PSA is manufactured on a second wafer, which differs from the first wafer, and then, the upper chip is connected to the lower chip by a bonding process. For example, the bonding process may denote a process of electrically connecting a bonding metal, formed on an uppermost metal layer of the upper chip, to a bonding metal formed on an uppermost metal layer of the lower chip. For example, when the bonding metal includes copper (Cu), the bonding process may be a Cu-to-Cu bonding process, and in some example embodiments, the bonding metal may include aluminum (Al) and/or tungsten (W).

The peripheral circuit structure PSA may be bonded to the cell array structure CSA by a bonding via VIA so that a wiring line ML and a bit line (not shown) face an interlayer insulation layer 80 of the peripheral circuit structure PSA. A second upper insulation layer 138 surrounding the bonding via VIA may contact the interlayer insulation layer 80, and the wiring line ML and the bit line may be electrically connected to the peripheral circuit structure PSA by the bonding via VIA. A plurality of gate electrodes 130 may have a width, which increases progressively in a horizontal direction as a distance to the peripheral circuit structure PSA increases. Although not shown, a passivation layer (not shown) and an external bonding pad (not shown) may be further provided on a top surface of a common source plate 110.

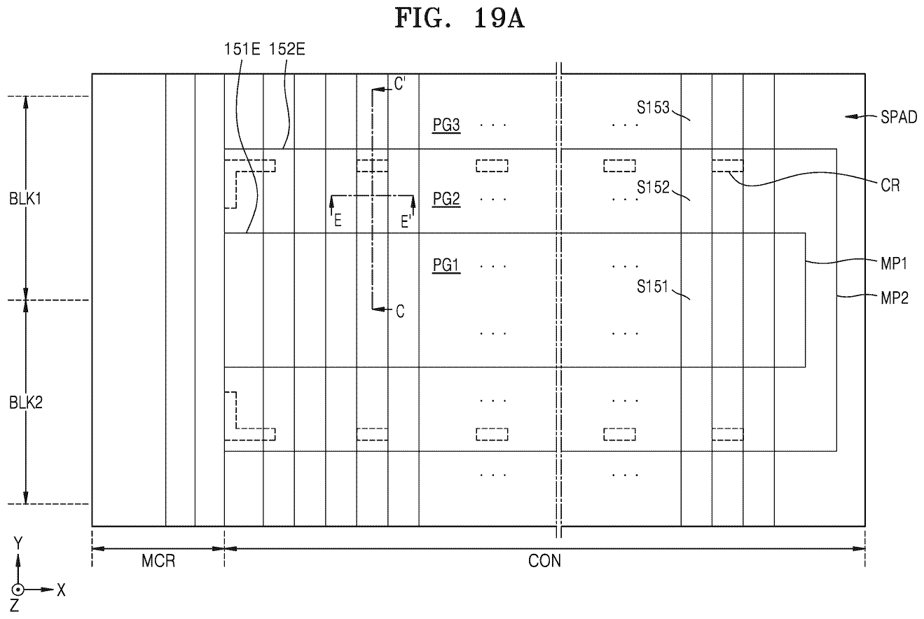

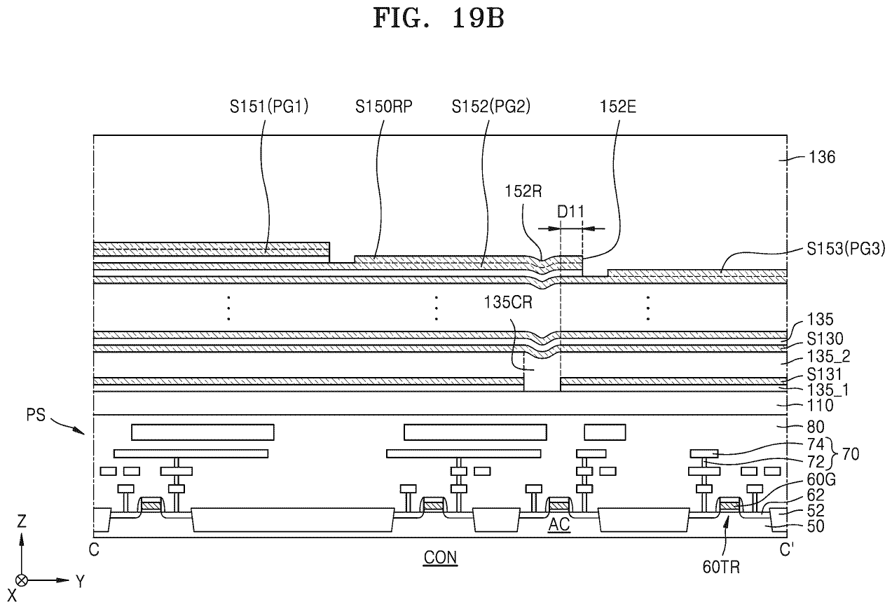

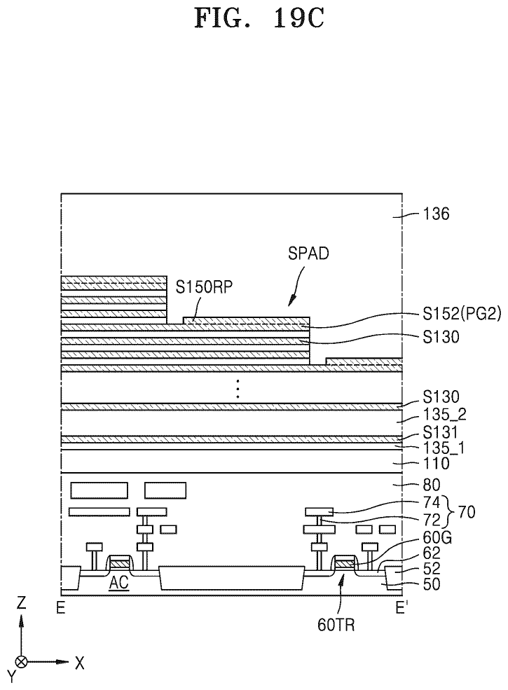

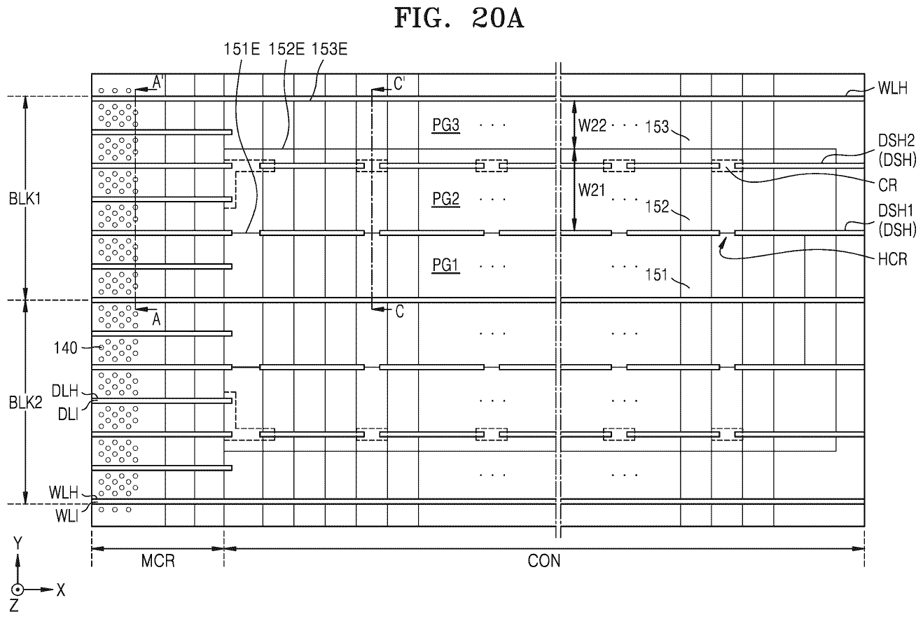

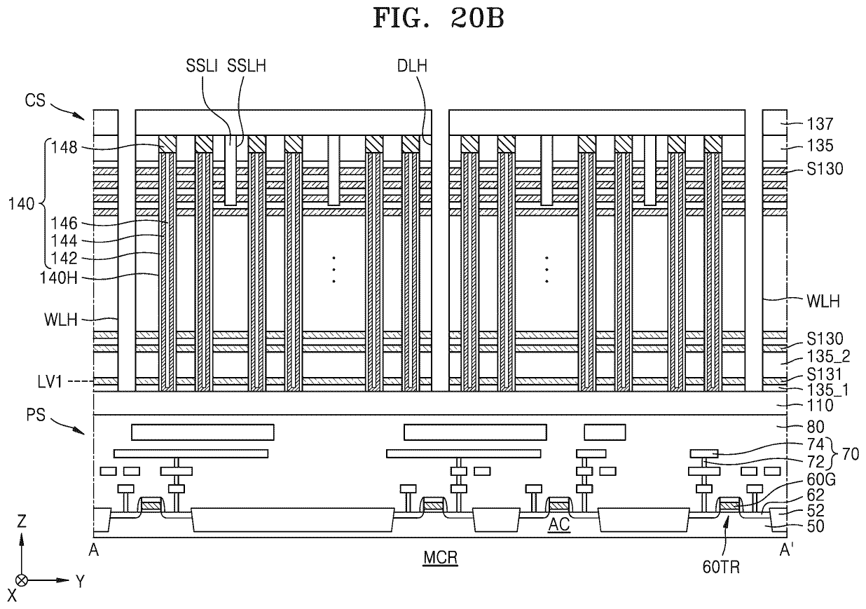

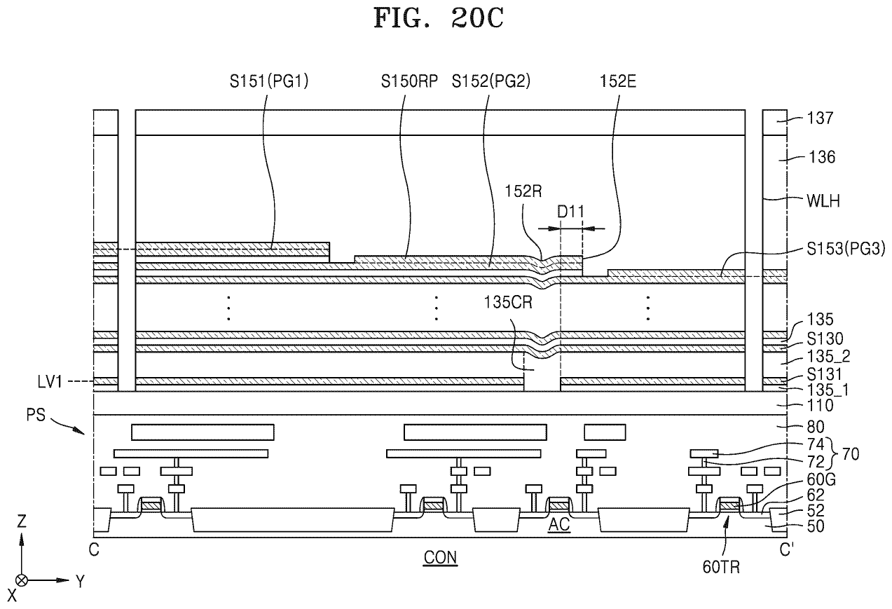

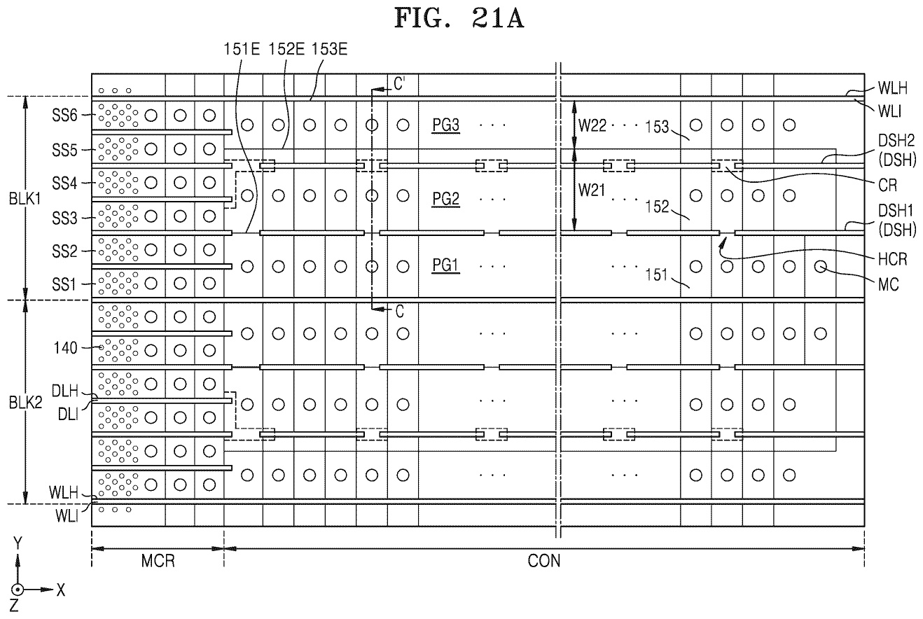

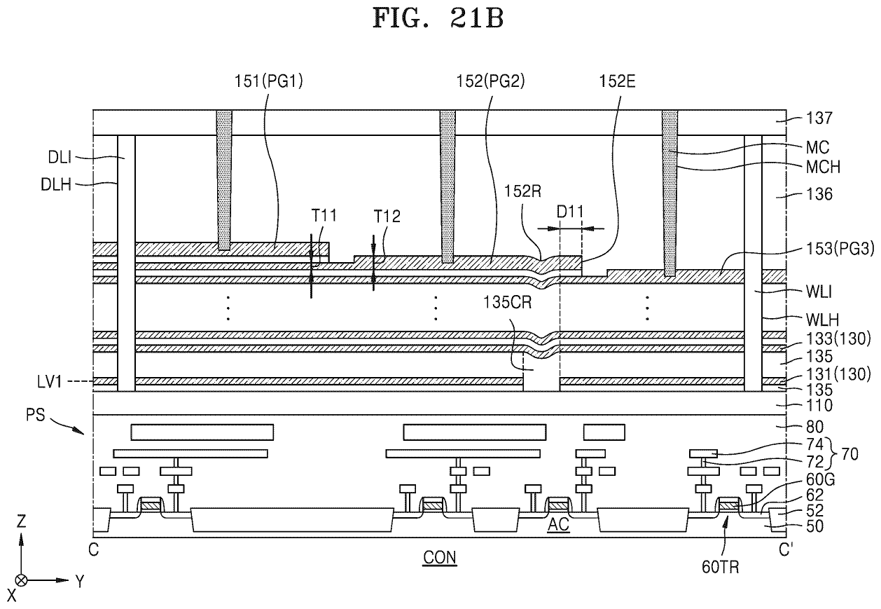

FIGS. 18A to 21B are cross-sectional views illustrating a method of manufacturing a semiconductor device 100, according to some example embodiments. In detail, FIGS. 18A, 19A, and 21A are plan views based on a manufacturing process sequence, FIG. 18B is a cross-sectional view taken along line C-C′ of FIG. 18A, FIGS. 19B and 19C are cross-sectional views respectively taken along line C-C′ and line E-E′ of FIG. 19A, FIGS. 20B and 20C are cross-sectional views respectively taken along line A-A′ and line C-C′ of FIG. 20A, and FIG. 21B is a cross-sectional view taken along line C-C′ of FIG. 21A.

Referring to FIGS. 18A and 18B, a peripheral circuit structure PS may be formed on a substrate 50. In some example embodiments, the substrate 50 may include a single crystalline silicon substrate. A plurality of peripheral circuit transistors 60TR may be formed on the substrate and a peripheral circuit wiring structure 70 and an interlayer insulation layer 80, which are electrically connected to the peripheral circuit transistors 60TR, may be formed on the substrate 50.

Subsequently, the common source plate 110 may be disposed on the interlayer insulation layer 80. In some example embodiments, the common source plate 110 may be formed by using a semiconductor doped with n-type impurities.

Subsequently, a first mold insulation layer 135_1 and a first sacrificial layer S131 may be sequentially formed on the common source plate 110, and a ground selection line cut region CR may be formed by removing a portion of the first sacrificial layer S131 with a mask pattern (not shown).

In some example embodiments, the first mold insulation layer 135_1 may include an insulation material, such as silicon oxide and/or silicon oxynitride, and the first sacrificial layer S131 may include silicon oxide, silicon oxynitride, and/or impurity-doped polysilicon.

Subsequently, a second mold insulation layer 135_2 may be formed on the first sacrificial layer S131, and a ground selection line insulation layer 135CR may be formed in the ground selection line cut region CR.

In some example embodiments, the ground selection line insulation layer 135CR may include a top surface disposed at a level, which is lower than an uppermost surface of the second mold insulation layer 135_2, and may include a recessed top surface RS, which is recessed downward. For example, the ground selection line insulation layer 135CR may include the same material as a material of the second mold insulation layer 135_2. In some example embodiments, the ground selection line insulation layer 135CR may include a material, which has good step coverage.

Referring to FIGS. 19A, 19B, and 19C, a plurality of sacrificial layers S130 and a plurality of mold insulation layers 135 may be alternately formed on the second mold insulation layer 135_2 and the ground selection line insulation layer 135CR. In some example embodiments, the plurality of mold insulation layers 135 may include an insulation material, such as silicon oxide and/or silicon oxynitride, and the plurality of sacrificial layers S130 may include silicon oxide, silicon oxynitride, and/or impurity-doped polysilicon.

Subsequently, a preliminary pad portion SPAD may be formed by patterning the plurality of mold insulation layers 135 and the plurality of sacrificial layers S130, in a connection region CON. In some example embodiments, the preliminary pad portion SPAD may be formed in a staircase shape having a top level difference in a first horizontal direction X and a second horizontal direction Y.

In some example embodiments, the preliminary pad portion SPAD may be formed to include a first pad group PG1, a second pad group PG2, and a third pad group PG3, the first pad group PG1 may include a plurality of first preliminary pad layers S151, the second pad group PG2 may include a plurality of second preliminary pad layers S152, and the third pad group PG3 may include a plurality of third preliminary pad layers S153. In some example embodiments, an edge 151E of the first pad group PG1 may be defined by a first mask pattern MP1, and an edge 152E of the second pad group PG2 may be defined by a second mask pattern MP2.

In some example embodiments, the first preliminary pad layer S151, the second preliminary pad layer S152, and the third preliminary pad layer S153 may be formed by performing a sequential trimming process using the second mask pattern MP2 and a sequential trimming process using the first mask pattern MP1. In some example embodiments, the first preliminary pad layer S151, the second preliminary pad layer S152, and the third preliminary pad layer S153 may be formed by performing a sequential trimming process using the first mask pattern MP1 and a sequential trimming process using the second mask pattern MP2.

Subsequently, a thickness reinforcement layer S150RP may be formed on an exposed top surface of the preliminary pad portion SPAD. In some example embodiments, the thickness reinforcement layer S150RP may be formed by sequentially performing a deposition process, a plasma process, and an etching process on an insulation layer.

A recessed top surface RS of the ground selection line insulation layer 135CR may be disposed at a level which is lower than a top surface of the second mold insulation layer 135_2 and may include a curved profile, and thus, the second preliminary pad layer S152 and the sacrificial layer S130 disposed on the ground selection line insulation layer 135CR may be formed to include a bending portion 152R. An edge 152E of the second preliminary pad layer S152 may be arranged apart from the bending portion 152R in the second horizontal direction Y, and thus, the occurrence of a bridge defect of the second preliminary pad layer S152 may be prevented (or the occurrence of reduced) in a process for forming the second preliminary pad layer S152 and/or a process for forming the thickness reinforcement layer S150RP on the second preliminary pad layer S152. For example, one second preliminary pad layer S152 and another second preliminary pad layer S152 thereunder, which are disposed adjacent to each other in the first horizontal direction X, may be completely detached from each other, or one second preliminary pad layer S152 and a third preliminary pad layer S153 thereunder, which are disposed adjacent to each other in the second horizontal direction Y, may be completely detached from each other.

Subsequently, a cover insulation layer 136 covering the preliminary pad portion SPAD may be formed. The cover insulation layer 136 may include an insulation material, such as silicon oxide and/or silicon oxynitride.

Referring to FIGS. 20A to 20C, a mask pattern (not shown) may be formed on the uppermost mold insulation layer 135 and the cover insulation layer 136, and a channel hole 140H may be formed by patterning the plurality of mold insulation layers 135 and the plurality of sacrificial layers S130 by using the mask pattern as an etch mask.

Subsequently, a channel structure 140 including the gate insulation layer 142, the channel layer 144, the buried insulation layer 146, and the conductive plug 148 may be formed on an inner wall of the channel hole 140H.

Subsequently, a first upper insulation layer 137 may be disposed on the uppermost mold insulation layer 135 and the cover insulation layer 136. Subsequently, a mask pattern (not shown) may be formed on the first upper insulation layer 137, and a gate stack separation opening portion WLH, a dummy stack separation opening portion DLH, and a dummy stack opening portion DSH may be formed by removing a portion of each of the plurality of mold insulation layers 135 and the plurality of sacrificial layers S130 by using the mask pattern as an etch mask.

Referring to FIGS. 21A and 21B, the plurality of sacrificial layers S130, exposed at a sidewall of each of the gate stack separation opening portion WLH, the dummy stack separation opening portion DLH, and the dummy stack opening portion DSH, may be removed. In some example embodiments, a process of removing the plurality of sacrificial layers S130 may be a wet etching process which uses a phosphoric acid solution as an etchant. As the plurality of sacrificial layers S130 are removed, a portion of a sidewall of the channel structure 140 may be exposed.

Subsequently, the plurality of gate electrodes 130 may be formed by filling a conductive material at positions from which the plurality of sacrificial layers S130 are removed. Subsequently, a gate stack separation insulation layer WLI, a dummy stack separation insulation layer DLI, and a dummy stack insulation layer DSI may be formed by filling an insulation material into the gate stack separation opening portion WLH, the dummy stack separation opening portion DLH, and the dummy stack opening portion DSH, respectively.

Subsequently, a cell contact hole MCH passing through the first upper insulation layer 137 and the cover insulation layer 136 may be formed. Subsequently, a cell contact plug MC electrically connected to a pad portion PAD may be formed by filling a conductive material into the cell contact hole MCH.

Referring to FIGS. 4 to 11, a bit line contact BLC which passes through the first upper insulation layer 137 and is electrically connected to the channel structure 140 may be formed.

Subsequently, a bit line BL electrically connected to the bit line contact BLC in the memory cell region MCR may be formed, and a wiring line ML electrically connected to the cell contact plug MC in the connection region CON may be formed. Subsequently, a second upper insulation layer 138 covering the wiring line ML and the bit line BL may be disposed on the first upper insulation layer 137.

The semiconductor device 100 may be finished by performing the processes described above.

According to the embodiments described above, a pad layer bridge defect, which occurs when the ground selection line cut region CR is disposed at a position vertically overlapping the edge 151E of each of the plurality of first pad layers 151 and the edge 152E of each of the plurality of second pad layers 152, and thus occurs when the first and second pad layers 151 and 152 are not sufficiently detached from another first and second pad layers 151 and 152 thereunder due to a bending portion, may be avoided or the occurrence thereof reduced.

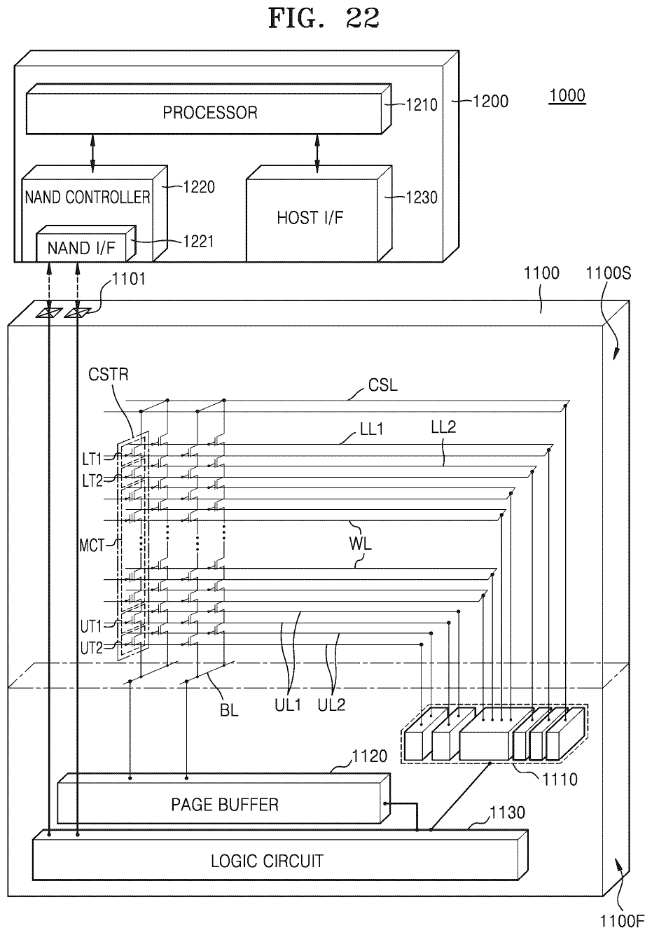

FIG. 22 is a diagram schematically illustrating a data storage system 1000 including a semiconductor device, according to some example embodiments.

Referring to FIG. 22, the data storage system 1000 may include one or more semiconductor devices 1100 and a memory controller 1200 electrically connected to the semiconductor devices 1100. The data storage system 1000 may include, for example, a solid state drive (SSD) device, a universal serial bus (USB), a computing system, a medical device, and/or a communication device, which includes the one or more semiconductor devices 1100.

The semiconductor device 1100 may be a non-volatile semiconductor device, and for example, the semiconductor device 1100 may include a NAND flash semiconductor device including one of the semiconductor devices 10, 100, 100A, 100B, and 200 described above with reference to FIGS. 1 to 17. The semiconductor device 1100 may include a first structure 1100F and a second structure 1100S on the first structure 1100F. The first structure 1100F may include a row decoder 1110, a page buffer 1120, and a logic circuit 1130.

The second structure 1100S may include a memory cell structure including a bit line BL, a common source line CSL, a plurality of word lines WL, first and second string selection lines UL1 and UL2, first and second ground selection lines LL1 and LL2, and a plurality of memory cell strings CSTR between the bit line BL and the common source line CSL.

In the second structure 1100S, each of the plurality of memory cell strings CSTR may include ground selection transistors LT1 and LT2 adjacent to the common source line CSL, string selection transistors UT1 and UT2 adjacent to the bit line BL, and a plurality of memory cell transistors MCT disposed between the ground selection transistors LT1 and LT2 and the string selection transistors UT1 and UT2. The number of ground selection transistors LT1 and LT2 and the number of string selection transistors UT1 and UT2 may be variously changed according to some example embodiments.

In some example embodiments, a plurality of ground selection lines LL1 and LL2 may be respectively connected to gate electrodes of the ground selection transistors LT1 and LT2. The word line WL may be connected to a gate electrode of the memory cell transistor MCT. A plurality of string selection lines UL1 and UL2 may be respectively connected to gate electrodes of the string selection transistors UT1 and UT2.

The common source line CSL, the plurality of ground selection lines LL1 and LL2, the plurality of word lines WL, and the plurality of string selection lines UL1 and UL2 may be connected to the row decoder 1110. The plurality of bit lines BL may be electrically connected to the page buffer 1120.

The semiconductor device 1100 may communicate with the memory controller 1200 through an input/output (I/O) pad 1101 electrically connected to the logic circuit 1130. The I/O pad 1101 may be electrically connected to the logic circuit 1130.

The memory controller 1200 may include a processor 1210, a NAND controller 1220, and a host interface 1230. In some example embodiments, the data storage system 1000 may include a plurality of semiconductor devices 1100, and in this case, the memory controller 1200 may control a plurality of semiconductor devices 1100.

The processor 1210 may control an overall operation of the data storage system 1000 including the memory controller 1200. The processor 1210 may operate based on certain firmware and may control the NAND controller 1220 to access the semiconductor device 1100. The NAND controller 1220 may include an NAND interface 1221 which processes communication with the semiconductor device 1100. A control command for controlling the semiconductor device 1100, data which is to be recorded in the plurality of memory cell transistors MCT of the semiconductor device 1100, and data which is to be read from the plurality of memory cell transistors MCT of the semiconductor device 1100 may be transferred through the NAND interface 1221. The host interface 1230 may provide a communication function between the data storage system 1000 and an external host. When a control command is received from the external host through the host interface 1230, the processor 1210 may control the semiconductor device 1100 in response to the control command.

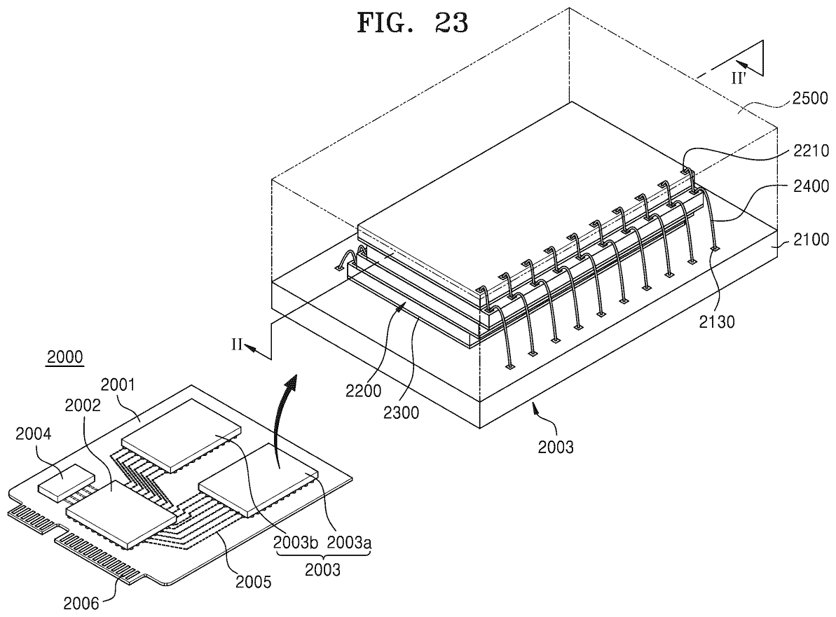

FIG. 23 is a perspective view schematically illustrating a data storage system 2000 including a semiconductor device, according to some example embodiments.

Referring to FIG. 23, the data storage system 2000 according to some example embodiments may include a main substrate 2001, a memory controller 2002 mounted on the main substrate 2001, one or more semiconductor packages 2003, and dynamic random access memory (RAM) (DRAM) 2004. The semiconductor package 2003 and the DRAM 2004 may be connected to the memory controller 2002 by a plurality of wiring patterns 2005 formed on the main substrate 2001.

The main substrate 2001 may include a connector 2006 including a plurality of pins coupled to the external host. In the connector 2006, the number and arrangement of pins may be changed based on a communication interface between the data storage system 2000 and the external host. In some example embodiments, the data storage system 2000 may communicate with the external host, based on one of interfaces such as USB, peripheral component interconnect express (PCI-Express), serial advanced technology attachment (SATA), and M-Phy for universal flash storage (UFS). In some example embodiments, the data storage system 2000 may operate with power supplied from the external host through the connector 2006. The data storage system 2000 may further include a power management integrated circuit (PMIC) which divides power, supplied from the external host, to the memory controller 2002 and the semiconductor package 2003.

The memory controller 2002 may record data in the semiconductor package 2003 or may read data from the semiconductor package 2003, and may improve an operation speed of the data storage system 2000.

The DRAM 2004 may be a buffer memory for reducing a speed difference between the external host and the semiconductor package 2003 which is a data storage space. The DRAM 2004 included in the data storage system 2000 may operate as a cache memory and may provide a space for temporarily storing data in a control operation performed on the semiconductor package 2003. When the DRAM 2004 is included in the data storage system 2000, the memory controller 2002 may further include a DRAM controller for controlling the DRAM 2004, in addition to a NAND controller for controlling the semiconductor package 2003.

The semiconductor package 2003 may include first and second semiconductor packages 2003a and 2003b apart from each other. Each of the first and second semiconductor packages 2003a and 2003b may include a semiconductor package including a plurality of semiconductor chips 2200. Each of the first and second semiconductor packages 2003a and 2003b may include a package substrate 2100, the plurality of semiconductor chips 2200 on the package substrate 2100, an adhesive layer 2300 disposed on a bottom surface of each of the plurality of semiconductor chips 2200, a connection structure 2400 electrically connecting the plurality of semiconductor chips 2200 to the package substrate 2100, and a molding layer 2500 covering the plurality of semiconductor chips 2200 and the connection structure 2400 on the package substrate 2100.

The package substrate 2100 may include a printed circuit board including a plurality of package upper pads 2130. The plurality of semiconductor chips 2200 may each include an I/O pad 2210. The I/O pad 2210 may correspond to the I/O pad 101 of FIG. 22. Each of the plurality of semiconductor chips 2200 may include at least one of the semiconductor devices 10, 100, 100A, 100B, and 200 described above with reference to FIGS. 1 to 17.

In some example embodiments, the connection structure 2400 may be a bonding wire which electrically connects the I/O pad 2210 to the package upper pad 2130. Therefore, in the first and second semiconductor packages 2003a and 2003b, the plurality of semiconductor chips 2200 may be electrically connected to one another by a bonding wire scheme and may be electrically connected to the package upper pad 2130 of the package substrate 2100. In some example embodiments, in the first and second semiconductor packages 2003a and 2003b, the plurality of semiconductor chips 2200 may be electrically connected to one another by a connection structure including a through silicon via (TSV), instead of the connection structure 2400 based on the bonding wire scheme.

In some example embodiments, the memory controller 2002 and the plurality of semiconductor chips 2200 may be included in one package. In an embodiment, the memory controller 2002 and the plurality of semiconductor chips 2200 may be mounted on a separate interposer substrate which differs from the main substrate 2001, and the memory controller 2002 may be connected to the plurality of semiconductor chips 2200 by a wiring formed on the interposer substrate.

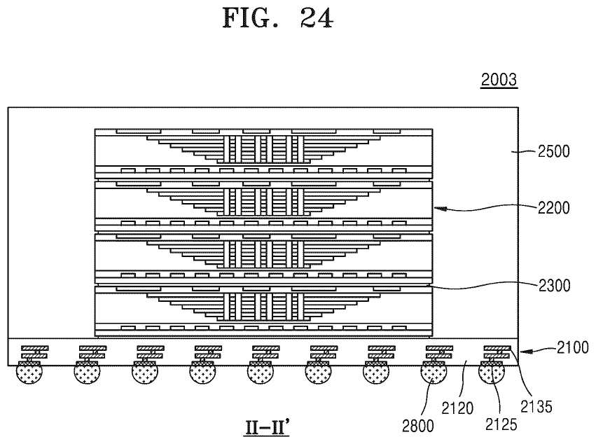

FIG. 24 is a cross-sectional view schematically illustrating semiconductor packages 2003 according to some example embodiments. FIG. 24 is a cross-sectional view taken along line II-II′ of FIG. 23.

Referring to FIG. 24, in the semiconductor package 2003, a package substrate 2100 may include a printed circuit board. The package substrate 2100 may include a package substrate body portion 2120, a plurality of package upper pads 2130 (see FIG. 23) disposed on a top surface of the package substrate body portion 2120, a plurality of lower pads 2125 disposed on or exposed through a bottom surface of the package substrate body portion 2120, and a plurality of internal wirings 2135 electrically connecting the plurality of package upper pads 2130 (see FIG. 23) to the plurality of lower pads 2125 in the package substrate body portion 2120. As illustrated in FIG. 24, the plurality of package upper pads 2130 may be electrically connected to a plurality of connection structures 2400. As illustrated in FIG. 23, the plurality of lower pads 2125 may be connected to, through a plurality of conductive bumps 2800, a plurality of wiring patterns 2005 on the main substrate 2001 of the data storage system 2000 illustrated in FIG. 23. Each of the plurality of semiconductor chips 2200 may include at least one of the semiconductor devices 10, 100, 100A, 100B, and 200 described above with reference to FIGS. 1 to 17.

The semiconductor devices 10, 100, 100A, 100B, 200 and subcomponents thereof (or other circuitry, for example, data storage system 1000, the semiconductor devices 1100, the memory controller 1200, data storage system 2000, and subcomponents thereof) may include hardware including logic circuits; a hardware/software combination such as a processor executing software; or a combination thereof. For example, the processing circuitry more specifically may include, but is not limited to, a central processing unit (CPU) , an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

Hereinabove, exemplary embodiments have been described in the drawings and the specification. Example embodiments have been described by using the terms described herein, but this has been merely used for describing the inventive concepts and has not been used for limiting a meaning or limiting the scope of the inventive concepts defined in the following claims. Therefore, it may be understood by those of ordinary skill in the art that various modifications and other equivalent embodiments may be implemented from the inventive concepts. Accordingly, the spirit and scope of the inventive concepts may be defined based on the spirit and scope of the following claims.

While the inventive concepts have been particularly shown and described with reference to some example embodiments thereof, it will be understood that various changes in form and details may be made therein without departing from the spirit and scope of the following claims.

What is claimed is:

1. A semiconductor device comprising:
a substrate including a memory cell region and a connection region;
a plurality of gate electrodes in the memory cell region of the substrate and arranged apart from one another in a vertical direction perpendicular to a top surface of the substrate, the plurality of gate electrodes including at least one ground selection line and a plurality of word lines arranged at a vertical level which is higher than the at least one ground selection line;
a pair of gate stack separation insulation layers passing through the plurality of gate electrodes and extending in a first horizontal direction in the memory cell region and the connection region of the substrate; and
a pad structure including a plurality of pad layers in the connection region of the substrate, connected to respective ones of the plurality of gate electrodes, arranged in a staircase shape in the first horizontal direction, and arranged in a staircase shape in a second horizontal direction vertical to the first horizontal direction,
the at least one ground selection line comprising a plurality of ground selection line cut regions, and each of the plurality of ground selection line cut regions being arranged apart from edges of the plurality of pad layers in the second horizontal direction.

2. The semiconductor device of claim 1, wherein each of the plurality of ground selection line cut regions does not vertically overlap the edges of the plurality of pad layers.

3. The semiconductor device of claim 1, further comprising a plurality of ground selection line insulation layers respectively filling the plurality of ground selection line cut regions of the at least one ground selection line,
wherein each of the plurality of ground selection line insulation layers does not vertically overlap the edges of the plurality of pad layers.

4. The semiconductor device of claim 3, wherein
the plurality of gate electrodes between the pair of gate stack separation insulation layers comprise one block,
the at least one ground selection line included in the one block comprises a first ground selection line and a second ground selection line electrically isolated from each other and arranged apart from each other in the second horizontal direction, and
the plurality of ground selection line insulation layers are arranged apart from each other between the first ground selection line and the second ground selection line.

5. The semiconductor device of claim 3, wherein each of the plurality of ground selection line insulation layers comprises a recessed top surface bent downward.

6. The semiconductor device of claim 3, wherein
a portion of each of the plurality of word lines, at a position vertically overlapping a corresponding ground selection line cut region, comprises a bending portion bent downward,
each of the plurality of ground selection line cut regions has a first width in the second horizontal direction, and
the bending portion has a second width which is less than the first width in the second horizontal direction.

7. The semiconductor device of claim 1, wherein
each of the plurality of gate electrodes has a first thickness in the vertical direction, and
each of the plurality of pad layers has a second thickness which is greater than the first thickness in the vertical direction.

8. The semiconductor device of claim 1, further comprising a plurality of dummy stack opening portions between the pair of gate stack separation insulation layers to pass through the plurality of gate electrodes and extend in the first horizontal direction, in a plan view, and
at least one of the plurality of dummy stack opening portions and a corresponding ground selection line cut region are on a straight line in the first horizontal direction.

9. The semiconductor device of claim 1, wherein the plurality of pad layers comprise:
a first pad layer;
a second pad layer adjacent to the first pad layer in the second horizontal direction and at a vertical level which is lower than the first pad layer; and
a third pad layer adjacent to the second pad layer in the second horizontal direction and at a vertical level which is lower than the second pad layer, and
the second pad layer has a third width in the second horizontal direction, and the third pad layer has a fourth width which is less than the third width in the second horizontal direction.

10. The semiconductor device of claim 9, wherein
each of the plurality of ground selection line cut regions is in the second pad layer and each of the plurality of ground selection line cut regions does not to vertically overlap an edge of the second pad layer in a plan view, and
the first pad layer does not vertically overlap each of the plurality of ground selection line cut regions.

11. A semiconductor device comprising:
a substrate including a memory cell region and a connection region;
a plurality of gate electrodes in the memory cell region of the substrate and arranged apart from one another in a vertical direction perpendicular to a top surface of the substrate, the plurality of gate electrodes including at least one ground selection line and a plurality of word lines arranged at a vertical level which is higher than the at least one ground selection line, and the at least one ground selection line including a plurality of ground selection line cut regions;
a pair of gate stack separation insulation layers passing through the plurality of gate electrodes and extending in a first horizontal direction in the memory cell region and the connection region of the substrate;
a plurality of channel structures arranged in the memory cell region of the substrate to pass through the plurality of gate electrodes and extend in the vertical direction;
a pad structure including a plurality of pad layers in the connection region of the substrate and connected to respective ones of the plurality of gate electrodes, the pad structure including a first pad group including a plurality of first pad layers arranged in a staircase shape in the first horizontal direction, a second pad group including a plurality of second pad layers arranged in a staircase shape in the first horizontal direction, and a third pad group including a plurality of third pad layers arranged in a staircase shape in the first horizontal direction;
a plurality of ground selection line insulation layers respectively filling the plurality of ground selection line cut regions of the at least one ground selection line; and
a plurality of dummy stack opening portions between the pair of gate stack separation insulation layers to pass through the plurality of gate electrodes and extend in the first horizontal direction, and
each of the plurality of ground selection line insulation layers vertically overlap the second pad group without vertically overlapping the first pad group.

12. The semiconductor device of claim 11, wherein each of the plurality of ground selection line cut regions does not vertically overlap edges of the plurality of second pad layers.

13. The semiconductor device of claim 11, wherein each of the plurality of ground selection line cut regions is in the second pad group in a plan view.

14. The semiconductor device of claim 11, wherein
the plurality of gate electrodes between the pair of gate stack separation insulation layers configure one block,
the at least one ground selection line included in the one block comprises a first ground selection line and a second ground selection line electrically isolated from each other and arranged apart from each other in a second horizontal direction, and
the plurality of ground selection line insulation layers are arranged apart from each other between the first ground selection line and the second ground selection line.

15. The semiconductor device of claim 14, wherein the plurality of dummy stack opening portions and the plurality of ground selection line insulation layers are arranged in a straight line in the first horizontal direction.

16. The semiconductor device of claim 11, wherein
a portion of each of the plurality of word lines, at a position vertically overlapping a corresponding ground selection line cut region, comprises a bending portion bent downward,
each of the plurality of ground selection line cut regions has a first width in a second horizontal direction, and
the bending portion has a second width which is less than the first width in the second horizontal direction.

17. The semiconductor device of claim 11, wherein
each of the plurality of second pad layers is arranged adjacent to a corresponding first pad layer of the plurality of first pad layers in a second horizontal direction and at a vertical level, which is lower than each of the plurality of first pad layers, and
each of the plurality of third pad layers is arranged adjacent to a corresponding second pad layer of the plurality of second pad layers in the second horizontal direction and at a vertical level, which is lower than each of the plurality of second pad layers.

18. The semiconductor device of claim 17, wherein
each of the plurality of second pad layers has a third width in the second horizontal direction, and
each of the plurality of third pad layers has a fourth width which is less than the third width in the second horizontal direction.

19. An electronic system comprising:
a main substrate;
a semiconductor device on the main substrate; and
a controller electrically connected to the semiconductor device on the main substrate, the semiconductor device comprising
a substrate including a memory cell region and a connection region;
a plurality of gate electrodes in the memory cell region of the substrate and arranged apart from one another in a vertical direction perpendicular to a top surface of the substrate, the plurality of gate electrodes including at least one ground selection line and a plurality of word lines arranged at a vertical level which is higher than the at least one ground selection line;
a pair of gate stack separation insulation layers passing through the plurality of gate electrodes and extending in a first horizontal direction in the memory cell region and the connection region of the substrate; and
a pad structure including a plurality of pad layers in the connection region of the substrate, connected to respective ones of the plurality of gate electrodes, arranged in a staircase shape in the first horizontal direction, and arranged in a staircase shape in a second horizontal direction vertical to the first horizontal direction,
the at least one ground selection line comprising a plurality of ground selection line cut regions, and each of the plurality of ground selection line cut regions being arranged apart from edges of the plurality of pad layers in the second horizontal direction.

20. The electronic system of claim 19, wherein the pad structure comprises:
a first pad group including a plurality of first pad layers arranged in a staircase shape in the first horizontal direction;
a second pad group including a plurality of second pad layers arranged in a staircase shape in the first horizontal direction; and
a third pad group including a plurality of third pad layers arranged in a staircase shape in the first horizontal direction, and
each of the plurality of ground selection line cut regions vertically overlap the second pad group without vertically overlapping the first pad group.
